(19) United States
(12) Patent Application Publication
(10) Pub. No.: US 2025/0040144 A1
(43) Pub. Date: Jan. 30, 2025

(54) MEMORY DEVICE

(71) Applicant: Semiconductor Energy Laboratory Co., Ltd., Atsugi-shi (JP)

(72) Inventors: Shunpei YAMAZAKI, Setagaya (JP); Takanori MATSUZAKI, Atsugi (JP); Yuto YAKUBO, Atsugi (JP); Yuki OKAMOTO, Ebina (JP)

(21) Appl. No.: 18/780,650

(22) Filed: Jul. 23, 2024

(30) Foreign Application Priority Data
Jul. 28, 2023 (JP) 2023-123020

(51) Int. Cl. H10B 51/20; H01L 23/528; H01L 23/532; H01L 29/78; H01L 29/786; H10B 51/10; H10B 53/10; H10B 53/20

(52) U.S. Cl. CPC H10B 51/20; H01L 23/5283; H01L 23/53295; H01L 29/78391; H01L 29/7869; H10B 51/10; H10B 53/10; H10B 53/20

(57) ABSTRACT

A memory device with a novel structure. A first transistor includes a first oxide semiconductor layer, a first conductive layer, a second conductive layer, a third conductive layer, a fourth conductive layer, a first insulating layer, and a second insulating layer. A second transistor includes a second oxide semiconductor layer, the first conductive layer, a fifth conductive layer, a sixth conductive layer, a seventh conductive layer, a third insulating layer, and a fourth insulating layer. In a plan view, the first oxide semiconductor layer includes a region facing the first conductive layer with the first insulating layer therebetween and a region facing the second conductive layer with the second insulating layer therebetween. In a plan view, the second oxide semiconductor layer includes a region facing the fifth conductive layer with the third insulating layer therebetween and a region facing the sixth conductive layer with the fourth insulating layer therebetween. The first oxide semiconductor layer is provided in contact with the third conductive layer and the fourth conductive layer. The second oxide semiconductor layer is provided in contact with the first conductive layer and the seventh conductive layer. In a cross-sectional view, the third conductive layer includes a region overlapping with the first conductive layer, the second conductive layer, the fourth conductive layer, the fifth conductive layer, the sixth conductive layer, and the seventh conductive layer.

### BACKGROUND OF THE INVENTION

### 1. Field of the Invention

One embodiment of the present invention relates to a semiconductor device and the like.

Note that one embodiment of the present invention is not limited to the above technical field. The technical field of the invention disclosed in this specification and the like relates to an object, a method, or a manufacturing method. One embodiment of the present invention relates to a process, a machine, manufacture, or a composition of matter.

Note that in this specification and the like, a semiconductor device generally means a device that can function by utilizing semiconductor characteristics. Thus, a semiconductor element such as a transistor or a diode, a circuit including the semiconductor element, and the like are semiconductor devices. A display device, a light-emitting device, a lighting device, an electro-optical device, a memory device, an imaging device, a communication device, an electronic device, and the like may include a semiconductor element and/or a semiconductor circuit. A display device, a light-emitting device, a lighting device, an electro-optical device, a memory device, an imaging device, a communication device, an electronic device, and the like are referred to as a semiconductor device in some cases.

### 2. Description of the Related Art

A silicon-based semiconductor material is widely known as a material of a semiconductor thin film that can be used in a transistor. As another material, an oxide semiconductor has been attracting attention. It is known that the current flowing through a transistor including an oxide semiconductor in the non-conducting state (off state) is extremely low.

For example, Patent Document 1 discloses a memory device that can retain stored contents for a long time by utilizing a characteristic of a low leakage current of the transistor including an oxide semiconductor.

In recent years, demand for higher density of memory cells included in a memory device has risen with reductions in size and weight of electronic devices. For example, Patent Document 2 discloses a technique for increasing the density of a memory cell by stacking a plurality of element layers including vertical transistors using oxide semiconductor films.

### REFERENCES

### Patent Documents

[Patent Document 1] Japanese Published Patent Application No. 2012-256831

[Patent Document 2] PCT International Publication No. 2022/160885

### SUMMARY OF THE INVENTION

In the case where the plurality of element layers each including a memory cell are stacked as in Patent Documents 1 and 2, the density of the memory cell can be increased. However, as the density of the memory cell increases, the distance between wirings or the like connected to transistors is shortened, which might increase the influence of parasitic capacitance. This might make it difficult to control a conduction state (also referred to as an on state or on) and a non-conduction state (also referred to as an off state or off) of the transistor and to retain stored contents in the memory cell for a long time.

An object of one embodiment of the present invention is to provide a memory device with a novel structure. Another object of one embodiment of the present invention is to provide a memory device having reduced power consumption, increased operation speed, reduced size, or increased memory capacity.

Note that the description of these objects does not preclude the presence of other objects. In one embodiment of the present invention, there is no need to achieve all the objects. Other objects will be apparent from and can be derived from the description of the specification, the drawings, the claims, and the like.

One embodiment of the present invention is a memory device including a memory cell including a first transistor and a second transistor; the first transistor includes a first oxide semiconductor layer, a first conductive layer, a second conductive layer, a third conductive layer, a fourth conductive layer, a first insulating layer, and a second insulating layer; the second transistor includes a second oxide semiconductor layer, the first conductive layer, a fifth conductive layer, a sixth conductive layer, a seventh conductive layer, a third insulating layer, and a fourth insulating layer; in a plan view, the first oxide semiconductor layer includes a region facing the first conductive layer with the first insulating layer therebetween and a region facing the second conductive layer with the second insulating layer therebetween; in a plan view, the second oxide semiconductor layer includes a region facing the fifth conductive layer with the third insulating layer therebetween and a region facing the sixth conductive layer with the fourth insulating layer therebetween; the first oxide semiconductor layer is provided in contact with the third conductive layer and the fourth conductive layer; the second oxide semiconductor layer is provided in contact with the first conductive layer and the seventh conductive layer; in a cross-sectional view, the third conductive layer includes a region overlapping with the first conductive layer, the second conductive layer, the fourth conductive layer, the fifth conductive layer, the sixth conductive layer, and the seventh conductive layer; a first potential supplied to the second conductive layer in a period in which data is written to the memory cell is higher than a second potential supplied to the second conductive layer in a period in which the data is retained in the memory cell; a third potential supplied to the sixth conductive layer in a period in which the data is read from the memory cell is higher than a fourth potential supplied to the sixth conductive layer in a period in which the data is retained in the memory cell; the third potential is lower than the first potential; and the fourth potential is lower than the second potential.

In the memory device of one embodiment of the present invention, it is preferable that the memory cell include a capacitor and one electrode of the capacitor be electrically connected to the first conductive layer.

In the memory device of one embodiment of the present invention, the other electrode of the capacitor is preferably electrically connected to the sixth conductive layer.

In the memory device of one embodiment of the present invention, the first insulating layer or the second insulating layer preferably includes hafnium, zirconium, and oxygen.

In the memory device of one embodiment of the present invention, each of the first oxide semiconductor layer and the second oxide semiconductor layer preferably includes at least indium.

Note that other embodiments of the present invention will be described in the following embodiments with reference to the drawings.

One embodiment of the present invention can provide a memory device with a novel structure. Another embodiment of the present invention can provide a memory device having reduced power consumption, increased operation speed, reduced size, or increased memory capacity.

Note that the description of these effects does not preclude the existence of other effects. One embodiment of the present invention does not necessarily achieve all of these effects. Other effects will be apparent from and can be derived from the description of the specification, the drawings, the claims, and the like.

### BRIEF DESCRIPTION OF THE DRAWINGS

In the accompanying drawings:

FIG. 1A is a circuit diagram of a memory cell, and FIG. 1B is a timing chart of the memory cell;

FIG. 2A is a schematic view illustrating voltages of a memory cell, and FIGS. 2B and 2C are circuit diagrams of the memory cell;

FIG. 3A is a cross-sectional diagram of a transistor, and FIG. 3B is a plan view of the transistor;

FIG. 4A is a cross-sectional diagram of a transistor, and FIG. 4B is a circuit diagram of the transistor;

FIGS. 5A to 5C are circuit diagrams of memory cells;

FIGS. 6A to 6C are circuit diagrams of memory cells;

FIG. 7 is a timing chart of a memory cell;

FIGS. 8A and 8B are circuit diagrams of memory cells;

FIG. 9A is a schematic view of a memory array, and FIG. 9B is a schematic view of a memory cell;

FIGS. 10A and 10B are plan views of transistors, and FIGS. 10C and 10D are cross-sectional diagrams of the transistors;

FIGS. 11A to 11D are cross-sectional diagrams illustrating a method for forming a metal oxide of one embodiment of the present invention;

FIGS. 12A to 12D are cross-sectional diagrams illustrating a method for forming a metal oxide of one embodiment of the present invention;

FIG. 13A is a block diagram illustrating a structure example of a semiconductor device, and FIGS. 13B and 13C are perspective views each illustrating a structure example of the semiconductor device;

FIG. 14A is a block diagram illustrating a structure example of a cell array, and FIG. 14B is a circuit diagram of a memory cell;

FIG. 15A is a block diagram illustrating a structure example of a cell array, and FIG. 15B is a circuit diagram of a memory cell;

FIG. 16 illustrates a hierarchy of various kinds of memory devices;

FIGS. 17A to 17E each illustrate an application example of a memory device; and

FIGS. 18A to 18H each illustrate an example of an electronic device.

### DETAILED DESCRIPTION OF THE INVENTION

Embodiments will be described in detail with reference to the drawings. Note that the present invention is not limited to the following description, and it will be readily appreciated by those skilled in the art that modes and details can be modified in various ways without departing from the spirit and scope of the present invention. Therefore, the present invention should not be construed as being limited to the description in the following embodiments. Note that in the structures of the invention described below, the same portions or portions having similar functions are denoted by the same reference numerals in different drawings, and description of such portions is not repeated.

In this specification and the like, a high power supply potential V_{DD} (hereinafter, also simply referred to as “V_{DD}”, “H potential”, or “H”) is a power supply potential higher than a low power supply potential V_{SS} (hereinafter also simply referred to as “V_{SS}”, “L potential”, or “L”). Moreover, V_{SS} is a power supply potential lower than V_{DD}.

Unless otherwise specified, transistors described in this specification and the like are enhancement (normally-off) n-channel field-effect transistors. Thus, the threshold voltage (also referred to as “Vₜₕ”) is higher than 0 V. Unless otherwise specified, the phrase “an H potential is supplied to a gate of a transistor” means that “the transistor is turned on” in some cases. Also, unless otherwise specified, the phrase “an L potential is supplied to a gate of a transistor” means that “the transistor is turned off” in some cases.

In the drawings and the like, for easy understanding of the potential of a wiring, an electrode, or the like, “H” representing an H potential or “L” representing an L potential is sometimes written near the wiring, the electrode, or the like. In addition, enclosed “H” or “L” is sometimes written near a wiring, an electrode, or the like whose potential changes. Moreover, a symbol “x” is sometimes written on a transistor in an off state.

In this specification and the like, when a plurality of components denoted by the same reference numerals need to be distinguished from each other, “_1”, “_2”, “[n]”, “[m, n]”, and the like are sometimes added to the reference numerals. For example, the second wiring GL is sometimes referred to as a wiring GL[2].

### Embodiment 1

A memory device of one embodiment of the present invention will be described. In this embodiment, a structure example or the like of a memory cell included in the memory device of one embodiment of the present invention will be described with reference to the drawings.

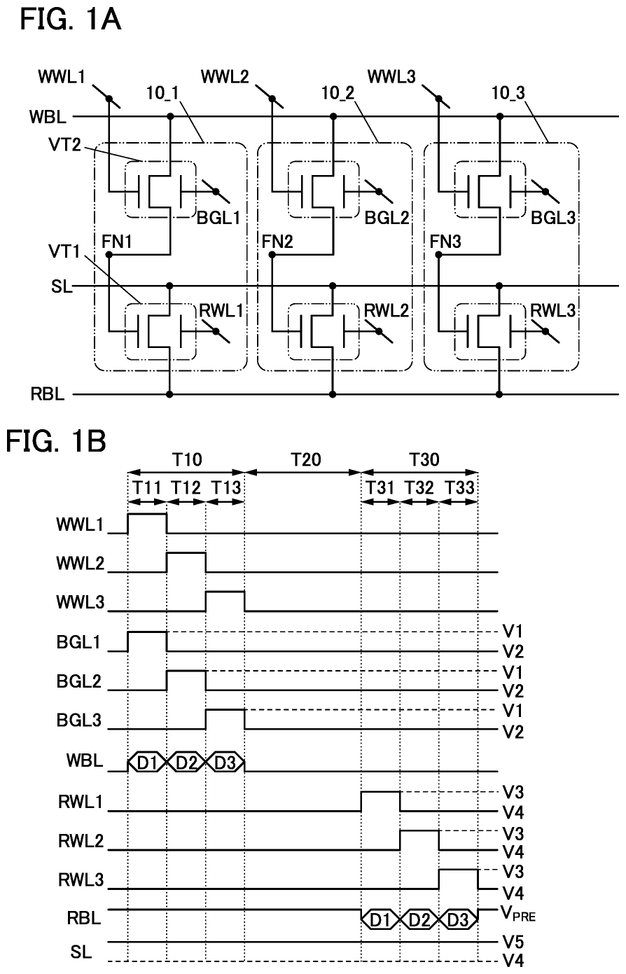

FIG. 1A illustrates an example of a circuit diagram of the memory cell included in the memory device of one embodiment of the present invention. FIG. 1A illustrates memory cells 10_1 to 10_3 as examples of the memory cells. The memory cells 10_1 to 10_3 each include a transistor VT1 and a transistor VT2.

Each of the memory cells 10_1 to 10_3 is connected to a wiring WBL, a wiring SL, and a wiring RBL. The memory cell 10_1 is connected to a wiring WWL1, a wiring BGL1, and a wiring RWL1. The memory cell 10_2 is connected to a wiring WWL2, a wiring BGL2, and a wiring RWL2. The memory cell 10_3 is connected to a wiring WWL3, a wiring BGL3, and a wiring RWL3.

The memory cells 10_1 to 10_3 can write data by controlling the on and off states of the transistor VT2 and supplying electric charge corresponding to the data to nodes FN1 to FN3. The wiring WBL is a wiring that transmits data (write data) to be written to the memory cells 10_1 to 10_3. The wirings WWL1 to WWL3 function as wirings that transmit word signals (write word signals) that control the timing of writing data retained in the memory cells 10_1 to 10_3. Specifically, data retained in the memory cells 10_1 to 10_3 can be written when the transistor VT2 is turned on. Electric charge corresponding to the data written to the memory cells 10_1 to 10_3 can be retained in the nodes FN1 to FN3 when the transistor VT2 is turned off. The wirings BGL1 to BGL3 function as wirings that transmit control signals for controlling the electrical characteristics, e.g., the threshold voltage, of the transistor VT2. The transistor VT2 functions as a transistor for data writing and data retention.

The memory cells 10_1 to 10_3 can read data on the basis of the difference in the amount of currents flowing through the transistor VT1, which changes in accordance with potentials of the nodes FN1 to FN3. The wiring RBL is a wiring that transmits data (read data) to be read from the memory cells 10_1 to 10_3. The wiring SL is a wiring for supplying a current, which corresponds to electric charge written between a source and a drain of the transistor VT1, to the wiring RBL. The wirings RWL1 to RWL3 function as wirings that transmit word signals (read word signals) that control the timing of reading data retained in the memory cells 10_1 to 10_3. Specifically, the threshold voltage of the transistor VT1 is shifted in the positive direction with a potential of the wiring RWL set to an L level, whereby a current does not flow through the transistor VT1 regardless of the potentials of the nodes FN1 to FN3. When the threshold voltage of the transistor VT1 is shifted to around 0, the amount of a current flowing through the transistor VT1 is changed in accordance with the potentials of the nodes FN1 to FN3. The transistor VT1 functions as a transistor for data reading.

The wiring WWL may be referred to as a write word line. The wiring RWL may be referred to as a read word line. The wiring WBL may be referred to as a write bit line. The wiring RBL may be referred to as a read bit line. The wiring SL may be referred to as a source line.

The transistors VT1 and VT2 are transistors (OS transistors) each including an oxide semiconductor in a channel formation region. A memory including a memory cell that includes an OS transistor is referred to as an “OS memory” in some cases. Examples of the oxide semiconductor used in the OS transistor include indium oxide (In oxide), gallium oxide (Ga oxide), and zinc oxide (Zn oxide). An clement layer including the OS transistor can be stacked over an element layer including a Si transistor. Thus, the transistor density per unit area can be increased.

The OS transistor has an extremely low off-state current. Accordingly, electric charge corresponding to data written to the memory cell 10 can be retained for a long time. In the case of the memory cell 10_1 illustrated in FIG. 1A, electric charge corresponding to data written through the transistor VT2 can be retained for a long time in the node FN1 to which a gate of the transistor VT1 is connected when the transistor VT2 is turned off. Also in the memory cell 10_2 or 10_3 illustrated in FIG. 1A, electric charge corresponding to data written through the transistor VT2 can be retained for a long time in the node FN2 or the node FN3, respectively. Therefore, the frequency of data refresh can be reduced, and the power consumption of the memory device of one embodiment of the present invention can be reduced.

In other words, the memory device provided with the memory cells 10_1 to 10_3 each including an OS transistor can be a nonvolatile oxide semiconductor random access memory (NOSRAM). For example, each of the memory cells 10_1 to 10_3 in FIG. 1A is a two-transistor (2T) NOSRAM. In the NOSRAM, data is rewritten by charge and discharge of electric charge; accordingly, a small amount of energy is consumed and thus the number of rewriting is theoretically not limited. The NOSRAM includes a transistor for data reading and thus has a high capability of supplying a signal of data that can be read through the wiring RBL; therefore, the NOSRAM is a memory that can operate at a high speed, has low power consumption, and has a high rewrite endurance. Furthermore, the NOSRAM can nondestructively read the written data, and thus is suitable for long-time data retention.

Furthermore, electrical characteristics of the OS transistor are better than those of a Si transistor in a high-temperature environment. Specifically, even at a high temperature higher than or equal to 125° C. and lower than or equal to 150° C., the OS transistor is capable of favorable switching operation owing to its high ratio of an on-state current to an off-state current. The OS transistor operates favorably within the range from −40° C. to 190° C. In other words, the OS transistor has significantly high heat resistance. This heat resistance is higher than the heat resistance of a phase change memory (PCM) (higher than or equal to −40° C. and lower than or equal to 150° C.), the heat resistance of a resistance random access memory (ReRAM) (higher than or equal to −40° C. and lower than or equal to 125° C.), the heat resistance of a magnetoresistive random access memory (MRAM) (higher than or equal to −40° C. and lower than or equal to 105° C.), and the like.

The transistors VT1 and VT2 included in each of the memory cells 10_1 to 10_3 that can be the 2T NOSRAMs illustrated in FIG. 1A are each a vertical transistor in which a source electrode and a drain electrode are positioned at different levels with respect to a formation surface like a substrate. In the vertical transistor, a current flows in the height direction (Z direction) in a channel formation region of a semiconductor layer. In other words, the channel length direction (vertical direction) includes a height component. Thus, the above-described vertical transistor can also be referred to as a vertical field effect transistor (VFET), a vertical channel transistor, a vertical transistor, or the like.

In the vertical transistor, a source region, a channel formation region, and a drain region can at least partly overlap with one another in a top view as compared with a horizontal transistor (also referred to as a planar transistor or a planar type transistor) in which a source electrode and a drain electrode are positioned at the same level; thus, the vertical transistor can have a small occupied area (also referred to as a footprint). Such a transistor enables reduced channel length and increased channel width, reducing the on-state resistance (increasing the on-state current).

Next, the operation of the memory device of one embodiment of the present invention will be described using the memory cells 10_1 to 10_3 illustrated in FIG. 1A as an example, with reference to FIG. 1B. FIG. 1B is a timing chart showing potential changes over time in signals (data, control signals, word signals, and the like) input to the wirings (the wirings WWL_1 to WWL_3, the wirings BGL_1 to BGL_3, the wiring WBL, the wirings RWL_1 to RWL_3, the wiring RBL, and the wiring SL). FIG. 1B shows the operation at the time of data writing (a period T10), the operation at the time of data retention (a period T20), and the operation at the time of data reading (a period T30).

Note that a period T11 to write data to the memory cell 10_1, a period T12 to write data to the memory cell 10_2, and a period T13 to write data to the memory cell 10_3 are provided in the period T10. A period T31 to read data from the memory cell 10_1, a period T32 to read data from the memory cell 10_2, and a period T33 to read data from the memory cell 10_3 are provided in the period T30.

In the memory cell 10_1 illustrated in FIG. 1A, data can be written to the memory cell 10_1 by supplying a control signal to the wiring BGL1, data to the wiring WBL, and a word signal to the wiring WWL1. By supplying a word signal to the wiring RWL1 and a precharge potential for data reading to the wiring RBL, data retained in the memory cell 10_1 can be read. By controlling the signals supplied to the wirings, data reading and data writing can be performed on the desired memory cells 10_1 to 10_3. Thus, the memory device including the memory cells 10_1 to 10_3 can function as an NOR memory device.

In the period T11 of the period T10, data D1 is written to the memory cell 10_1. Each of the wirings WWL1 and BGL1 is set to an H level. In the memory cell 10_1, the transistor VT2 can be turned on while its threshold voltage is shifted in the negative direction. Thus, the amount of a current flowing through the transistor VT2 in the memory cell 10_1 can be increased. As a result, a change in a potential of the node FN1 of the memory cell 10_1 can be made steep, and data writing can be performed at a high speed.

Similarly, in the periods T12 and T13 of the period T10, data D2 and data D3 are written to the memory cells 10_2 and 10_3, respectively. In the memory cells 10_2 and 10_3, the transistors VT2 can be turned on while their threshold voltages are shifted in the negative direction. Thus, the amount of currents flowing through the transistors VT2 in the memory cells 10_2 and 10_3 can be increased. As a result, changes in potentials of the node FN2 of the memory cell 10_2 and the node FN3 of the memory cell 10_3 can be made steep.

In the period T20, the data D1 to the data D3 are retained in the memory cells 10_1 to 10_3, respectively. The wirings WWL1 to WWL3 and the wirings BGL1 to BGL3 are each set to an L level. In the memory cells 10_1 to 10_3, the transistors VT2 can be turned off while their threshold voltages are shifted in the positive direction. Thus, the amount of currents flowing through the transistors VT2 in the memory cells 10_1 to 10_3 can be made extremely small. As a result, changes in potentials of the nodes FN1 to FN3 of the respective memory cells 10_1 to 10_3 can be made extremely small for a long time.

Note that the wirings RWL1 to RWL3 are each set to an L level during the periods T10 to T20. In the memory cells 10_1 to 10_3, the threshold voltages of the transistors VT2 are shifted largely in the positive direction. In this state, the amount of a current flowing between the source and the drain of the transistor VT1 can be small regardless of the potentials of the nodes FN1 to FN3. As a result, even when data is written to the memory cells 10_1 to 10_3, i.e., when the potentials of the nodes FN1 to FN3 are high, the transistor VT can be kept in an off state. In the period T31 of the period T30, the data D1 is read from the memory cell 10_1. The wiring RWL1 is set to an H level and the wiring RBL is set to a potential V_{PRE} for precharging. In the memory cell 10_1, the threshold voltage of the transistor VT1 can be shifted to around 0 V. A current can flow between the source and the drain of the transistor VT1 in accordance with a potential retained in the node FN1. Thus, in the memory cell 10_1, a potential of the wiring RBL can be changed in accordance with the amount of a current flowing through the transistor VT1, whereby the data D1 can be read.

Similarly, in the periods T32 and T33 of the period T30, the data D2 and the data D3 are read from the memory cells 10_2 and 10_3, respectively. In the memory cells 10_2 and 10_3, the wirings RWL2 and RWL3 are each set to an H level in this order. The threshold voltage of the transistor VT1 can be shifted to around 0 V. A current can flow between the source and the drain of the transistor VT1 in accordance with potentials retained in the nodes FN2 and FN3. Thus, in each of the memory cells 10_2 and 10_3, a potential of the wiring RBL can be changed in accordance with the amount of a current flowing through the transistor VT1, whereby the data D2 and the data D3 can be read.

Note that the H level potential and the L level potential are shown as V1 and V2, respectively, for signals of the wirings BGL_1 to BGL_3 in FIG. 1B. In FIG. 1B, the H level potential and the L level potential are shown as V3 and V4, respectively, for signals of the wirings RWL_1 to RWL_3. A potential of the wiring SL is shown in the drawing as a potential V5 that is at the same level as the potential V3. Note that when the potential V5 is higher than or equal to the potential V4 and lower than or equal to the potential V3, a current can flow through the transistor VT2 at a predetermined timing.

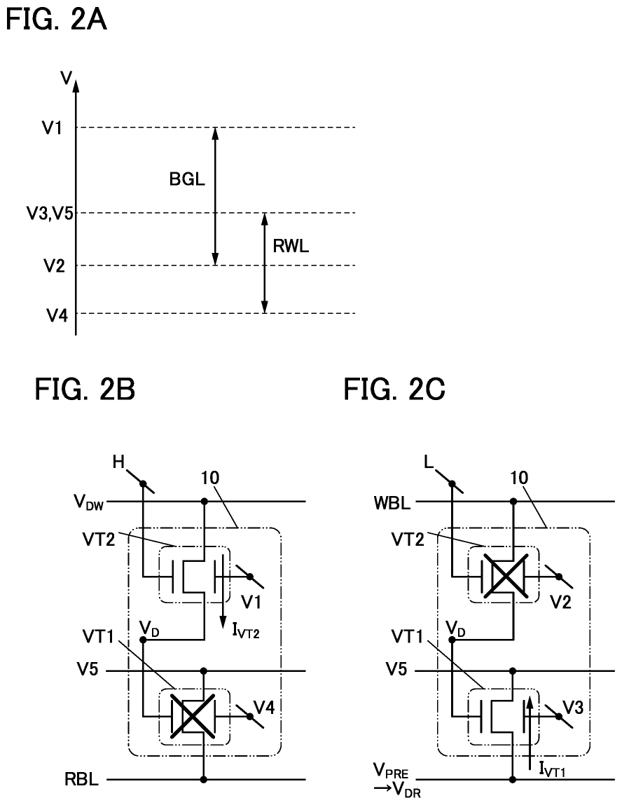

FIG. 2A is a schematic view showing differences in voltages among the potentials V1 to V5 in the memory cells 10_1 to 10_3. As shown in FIG. 2A, the potential V1 supplied to the wiring BGL (the wirings BGL_1 to BGL_3) is higher than the potential V2. That is, in each of the memory cells 10_1 to 10_3, the potential V1 supplied to the wiring BGL in a period in which data is written is higher than the potential V2 supplied to the wiring BGL in a period in which the data is retained.

As shown in FIG. 2A, the potential V3 supplied to the wiring RWL (the wirings RWL_1 to RWL_3) is higher than the potential V4. That is, in each of the memory cells 10_1 to 10_3, the potential V3 supplied to the wiring RWL in a period in which data is read is higher than the potential V4 supplied to the wiring RWL in a period in which the data is retained.

As shown in FIG. 2A, the potential V3 is lower than the potential V1, and the potential V4 is lower than the potential V2. That is, the potential V3 supplied to the wiring RWL in a period in which data is read is lower than the potential V1 supplied to the wiring BGL in a period in which data is written. Furthermore, the potential V4 supplied to the wiring RWL in a period in which data is retained is lower than the potential V2 supplied to the wiring BGL in a period in which data is retained.

As shown in FIG. 2A, potentials are set different among a control signal controlling the electrical characteristics of the transistor VT1, a control signal controlling the electrical characteristics of the transistor VT2, and a word signal controlling the timing of reading data to be supplied to the transistor VT2, whereby the electrical characteristics of the transistors VT1 and VT2 can be controlled in accordance with a period in which data is written, a period in which data is retained, and a period in which data is read.

Specifically, in a period in which data is written, a potential of each wiring is as illustrated in FIG. 2B, for example. In FIG. 2B, a potential V_{DW} supplied to a wiring corresponding to the wiring WBL represents a data potential to be written to the memory cell 10. In the transistor VT2, the potential V1 is supplied as a control signal. When the wiring WWL is set to an H level, a current I_{VT2} corresponding to the potential V_{DW} flows through the transistor VT2.

Meanwhile, in a period in which data is written as illustrated in FIG. 2B, the potential V4 is supplied as a word signal to the transistor VT1. Thus, the threshold voltage of the transistor VT1 can be shifted largely in the positive direction. The transistor VT1 can be in an off state (shown by ×) regardless of a data potential VD written to the node FN. As a result, the amount of a current flowing through the memory cell 10 can be made extremely small in a period in which data is written and a period in which data is retained.

In a period in which data is read, a potential of each wiring is as illustrated in FIG. 2C. In FIG. 2C, the potential V_{PRE} supplied to a wiring corresponding to the wiring RBL represents a precharge potential for reading data from the memory cell 10. In the transistor VT1, the potential V3 is supplied as a word signal. A current I_{VT1} flows through the transistor VT1 in accordance with the data potential V_{D} of the node FN. The amount of the current I_{VT1} increases when the data potential V_{D} is an H potential and decreases when the data potential V_{D} is an L potential. The potential V_{PRE} of the wiring RBL changes in accordance with the amount of the current I_{VT1}, so that a data potential V_{DR} can be read.

Meanwhile, in a period in which data is read as illustrated in FIG. 2C, the potential V2 is supplied as a control signal to the transistor VT2. The potential V2 is lower than the potential V1. Thus, the threshold voltage of the transistor VT1 can be shifted in the negative direction. Even when a potential of the wiring WWL at an L level changes, the transistor VT2 can be in an off state (shown by ×). As a result, the amount of change in a potential of the node FN can be made extremely small in a period in which data is retained and a period in which data is read.

The structures described with reference to FIGS. 2A to 2C are particularly effective when the above-described transistors VT1 and VT2 are vertical transistors and provided to overlap with each other. In the case where the vertical transistors VT1 and VT2 are provided to overlap with each other, the distance between wirings or the like connected to the transistors is shortened with an increase in the density of the memory cells, whereby the influence of parasitic capacitance is large. Thus, control of the on and off states of the transistor becomes difficult, in which case retention of stored contents in the memory cell for a long time might be difficult or an increase in power consumption might occur because a current flows through the memory cell in a period other than a reading period by a retained data potential.

In one embodiment of the present invention, a potential that controls the electrical characteristics, specifically, the threshold voltage, of the transistor is supplied to a conductive layer functioning as a first gate electrode or a second gate electrode of the vertical transistor. This structure allows different potentials to be supplied to each transistor in accordance with the write operation, the retention operation, or the read operation, so that the electrical characteristics of the transistor can be controlled. With this structure, a memory device having reduced power consumption, increased operation speed, reduced size, or increased memory capacity can be obtained.

Note that the first gate electrode of the vertical transistor is an electrode to which a signal for controlling the on and off states of the transistor is supplied. The second gate electrode of the vertical transistor is an electrode for supplying a potential for controlling the threshold voltage of the transistor. The second gate electrode can control the threshold voltage of the transistor to be shifted in the positive direction by applying a negative potential, so that the off-state current can be reduced. In addition, the second gate electrode can control the threshold voltage of the transistor to be shifted in the negative direction by applying a positive potential, so that the on-state current can be increased.

For example, in the case of the transistor VT2 in FIG. 1A, the electrode to which the wiring WWL is connected can be the first gate electrode, and the electrode to which the wiring BGL is connected can be the second gate electrode. Note that in the above example, the electrode functioning as the first gate electrode can be replaced with the electrode functioning as the second gate electrode when the connection between the wiring WWL and the wiring BGL is switched. The first gate electrode is referred to as a gate electrode in some cases. The second gate electrode is referred to as a back gate electrode in some cases.

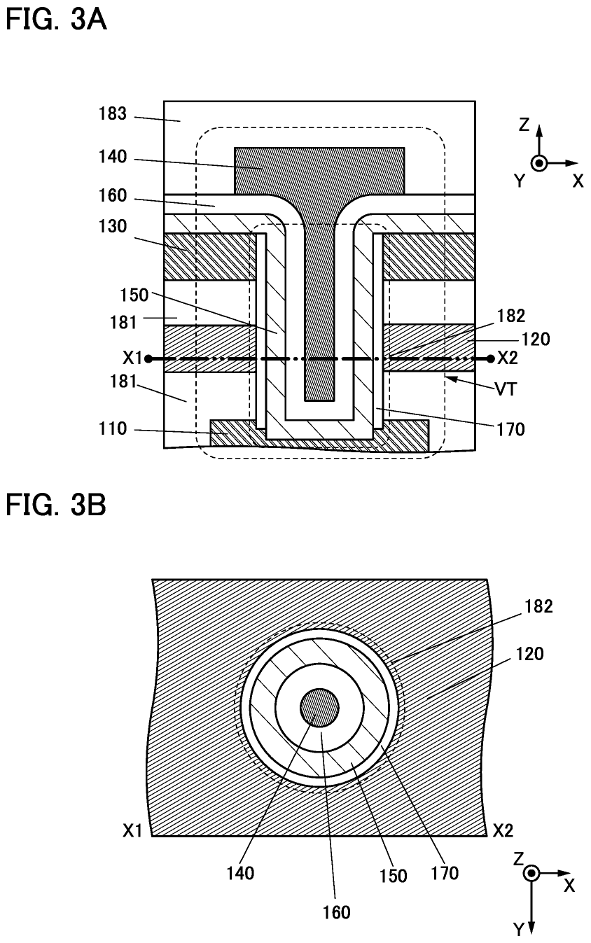

Next, a structure example of a vertical transistor that can be used as each of the transistors VT1 and VT2 illustrated in FIG. 1A will be described. FIG. 3A is a cross-sectional diagram of a transistor VT that can be used as each of the transistors VT1 and VT2, and FIG. 3B is a plan view along a dotted line X1-X2 in FIG. 3A.

Arrows indicating the X direction, the Y direction, and the Z direction are illustrated in the drawings or the like described below in some cases. The X direction, the Y direction, and the Z direction are orthogonal to each other. In this specification and the like, one of the X direction, the Y direction, and the Z direction is referred to as a “first direction” in some cases. One of the other two directions is referred to as a “second direction” in some cases. The remaining one of the directions is referred to as a “third direction” in some cases. The direction parallel to the XY plane is referred to as the horizontal direction, and the direction perpendicular to the XY plane is referred to as the vertical direction.

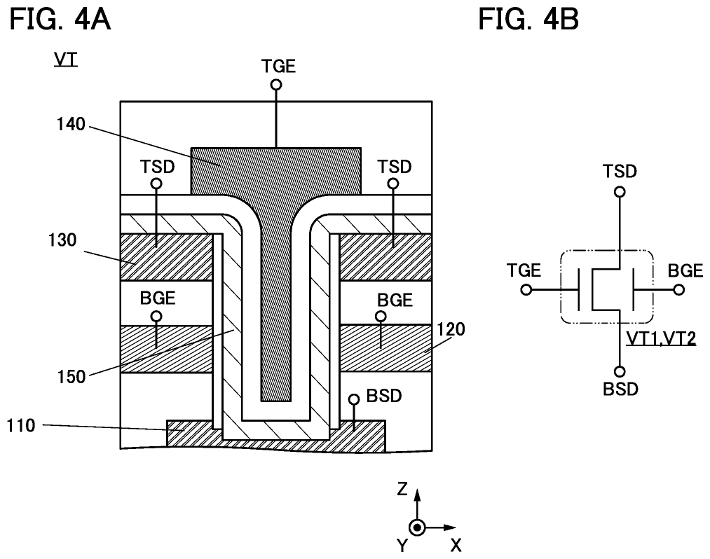

FIG. 4A illustrates a cross-sectional diagram in which terminals are added to the cross-sectional diagram illustrated in FIG. 3A. The terminals illustrated in FIG. 4A correspond to circuit symbols of the transistors VT1 and VT2 illustrated in FIG. 4B. As illustrated in FIGS. 4A and 4B, a conductive layer 110 functions as one of a source and a drain (a lower electrode BSD). A conductive layer 120 functions as one of the first gate electrode and the second gate electrode (a second gate electrode BGE). A conductive layer 130 functions as the other of the source and the drain (an upper electrode TSD). A conductive layer 140 functions as the other of the first gate electrode and the second gate electrode (a first gate electrode TGE). Note that the first gate electrode is an electrode to which a signal for controlling the on and off states of the transistor is supplied.

In FIG. 3A, the conductive layer 110 is provided over a substrate (not illustrated). An insulating layer 181 is provided over the conductive layer 110. The insulating layer 181 is provided with the conductive layer 120. The conductive layer 130 is provided over the conductive layer 181. An opening portion 182 is provided in a region of the insulating layer 181 overlapping with the conductive layer 110. An insulating layer 170 is provided in contact with a side surface of the opening portion 182. An oxide semiconductor layer 150 is in contact with a depressed portion of the conductive layer 110, a side surface of the insulating layer 170, and the top surface of the conductive layer 130. An insulating layer 160 is positioned inside the oxide semiconductor layer 150 in the opening portion 182. The conductive layer 140 is positioned inside the insulating layer 160 in the opening portion 182. An insulating layer 183 is provided over the conductive layer 140 and the insulating layer 160.

Note that the formation surface of the insulating layer or the like provided with the conductive layer 110 corresponds to the above-described XY plane. The above-described horizontal direction corresponds to the direction parallel to the formation surface of the conductive layer 110. The above-described Z direction corresponds to the direction perpendicular to the formation surface of the conductive layer 110.

The channel length of the transistor VT is the distance between a source region and a drain region, specifically, the distance from the conductive layer 110 to the conductive layer 130, which are in contact with the oxide semiconductor layer 150. That is, the channel length of the transistor VT can be set by the thickness of the insulating layer 181 over the conductive layer 110.

In a horizontal transistor, the channel length is limited by the light exposure limit of photolithography. In the structure in FIG. 3A, the channel length can be set by the thickness of the insulating layer 181. Thus, the channel length of the transistor VT can be extremely minute below the light exposure limit of photolithography. Accordingly, the transistor VT can have a higher on-state current and higher frequency characteristics. Thus, a memory device which operates at a high speed can be provided.

In addition, as described above, the channel formation region, the source region, and the drain region can be formed in the opening portion 182. Thus, the occupied area of the transistor VT can be reduced as compared with a horizontal transistor in which the channel formation region, the source region, and the drain region are provided separately on the XY plane. This allows high integration of the memory device; therefore, the memory capacity per unit area can be increased.

Note that the conductive layer 110 illustrated in FIG. 3A includes a depressed portion at a position overlapping with the opening portion 182. When the conductive layer 110 includes the depressed portion, the area where the oxide semiconductor layer 150 is in contact with the conductive layer 110 can be increased. Thus, the contact resistance between the oxide semiconductor layer 150 and the conductive layer 110 can be reduced.

In the plan view illustrated in FIG. 3B, which corresponds to the XY plane including the channel formation region of the oxide semiconductor layer 150, the conductive layer 140, the insulating layer 160, the oxide semiconductor layer 150, and the insulating layer 170 are concentrically provided. Thus, a side surface of the conductive layer 140 provided in the center faces a side surface of the oxide semiconductor layer 150 with the insulating layer 160 therebetween, and a side surface of the conductive layer 120 faces the side surface of the oxide semiconductor layer 150 with the insulating layer 170 therebetween. That is, all the perimeter of the oxide semiconductor layer 150 can be surrounded by the conductive layer with the insulating layer therebetween in the plan view. Thus, a region to be the channel formation region can be increased when the diameter of the opening portion 182 is made large. As a result, the channel width per unit area can be increased and the on-state current can be increased when the diameter of the opening portion 182 is made large.

In the structure in FIG. 3B, the insulating layer 170 is in contact with the outer surface of the oxide semiconductor layer 150. The conductive layer 120 surrounds all the perimeter of the oxide semiconductor layer 150 with the insulating layer 170 therebetween. The insulating layer 160 is in contact with the inner surface of the oxide semiconductor layer 150. The oxide semiconductor layer 150 surrounds all the perimeter of the conductive layer 140 with the insulating layer 160 therebetween. Thus, the channel formation region of the transistor VT can be formed over the entire surface of the oxide semiconductor layer 150 in the opening portion 182 (the entire region in contact with the insulating layers 160 and 170). Accordingly, the transistor VT of one embodiment of the present invention can have both a high on-state current and normally-off characteristics.

It is preferable that the channel formation region of the transistor including the oxide semiconductor layer contain less oxygen vacancies (V_{O}) or have a lower concentration of impurities such as hydrogen, nitrogen, or a metal element than the source region and the drain region. In some cases, hydrogen in the vicinity of an oxygen vacancy forms a defect that is an oxygen vacancy into which hydrogen enters (hereinafter sometimes referred to as V_{O}H), which generates an electron serving as a carrier. Therefore, it is preferable that the amount of V_{O}H be also reduced in the channel formation region. Thus, the channel formation region of the transistor is a high-resistance region having a low carrier concentration. Accordingly, the channel formation region of the transistor can be regarded as an i-type (intrinsic or substantially i-type region.

The source region and the drain region of the transistor including an oxide semiconductor in the semiconductor layer are regions which have lower resistances than the channel formation region by having increased carrier concentrations because of containing more oxygen vacancies or more V_{O}H or having higher concentrations of impurities such as hydrogen, nitrogen, or a metal element. In other words, the source region and the drain region of the transistor are n-type regions having higher carrier concentrations and lower resistances than the channel formation region.

The band gap of the oxide semiconductor is preferably greater than or equal to 2.0 eV, further preferably greater than or equal to 2.5 eV. The use of such an oxide semiconductor having a wide band gap as the semiconductor layer can reduce the off-state current of the transistor. By using a transistor with a low off-state current in a memory cell, stored contents can be retained for a long time. In other words, such a memory device does not require refresh operation or has an extremely low frequency of refresh operation, leading to a sufficient reduction in power consumption.

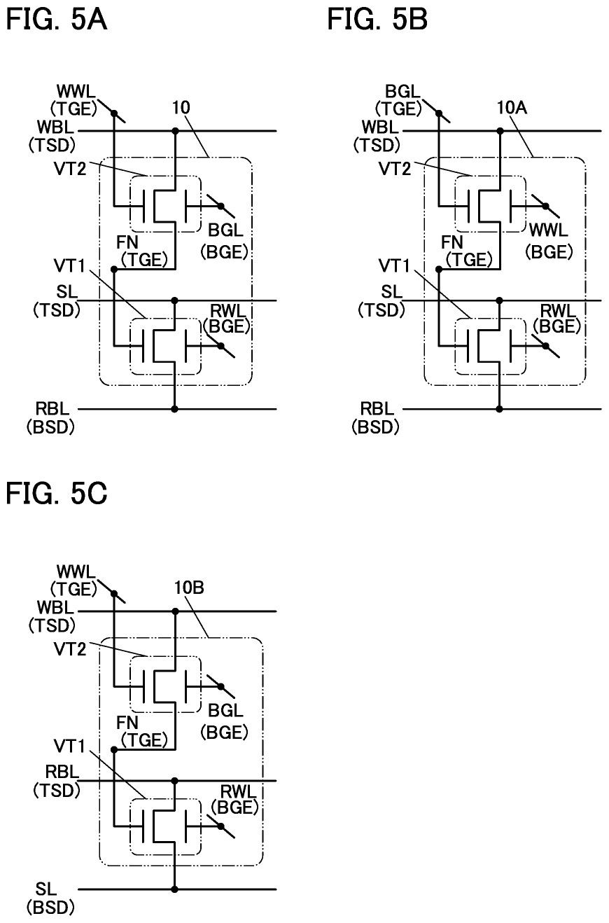

FIG. 5A is a diagram illustrating a structure example of the memory cell 10 that can be used as the memory cells 10_1 to 10_3 described with reference to FIG. 1A. In FIG. 5A, information on terminals of the transistors illustrated in FIGS. 4A and 4B (the lower electrode BSD, the second gate electrode BGE, the upper electrode TSD, and the first gate electrode TGE) is added to the reference numerals of the wirings.

As illustrated in FIG. 5A, the wiring WWL is connected to the first gate electrode TGE of the transistor VT2. As illustrated in FIG. 5A, the wiring WBL is connected to the upper electrode TSD of the transistor VT2. As illustrated in FIG. 5A, the wiring BGL is connected to the second gate electrode BGE of the transistor VT2. As illustrated in FIG. 5A, the node FN is connected to the first gate electrode TGE of the transistor VT1. The first gate electrode TGE of the transistor VT1 also has a function of the lower electrode BSD. As illustrated in FIG. 5A, the wiring RWL is connected to the second gate electrode BGE of the transistor VT1. As illustrated in FIG. 5A, the wiring SL is connected to the upper electrode TSD of the transistor VT1. As illustrated in FIG. 5A, the wiring RBL is connected to the lower electrode BSD of the transistor VT1.

Note that in some cases, the transistor of one embodiment of the present invention particularly preferably has a structure in which the conductive layer 140 is used as the first gate electrode TGE and the conductive layer 120 is used as the second gate electrode BGE. The conductive layer 140 has a wider region facing the oxide semiconductor layer 150 than the conductive layer 120; thus, when the conductive layer 140 is used as the first gate electrode TGE, a gate electric field is applied to the oxide semiconductor layer 150 more efficiently, so that the electrical characteristics of the transistor can be improved in some cases.

When the wirings are connected to the terminals of the transistor VT1 as illustrated in FIG. 5A, a region where the conductive layer 120 that is part of the wiring RWL, the conductive layer 130 that is part of the wiring SL, and the conductive layer 140 that is the node FN overlap with one another can be provided in the perpendicular direction of the conductive layer 110 that is part of the wiring RBL. Similarly, when the wirings are connected to the terminals of the transistor VT2, a region where the conductive layer 120 that is part of the wiring BGL, the conductive layer 130 that is part of the wiring WBL, and the conductive layer 140 that is part of the wiring WWL overlap with one another can be provided in the perpendicular direction of the conductive layer 140 that is the node FN.

Note that the structure of the memory cell that can be used as the memory cells 10_1 to 10_3 described with reference to FIG. 1A is not limited to the structure in FIG. 5A. For example, the structure in FIG. 5B or FIG. 5C may be employed. A memory cell 10A illustrated in FIG. 5B has a structure in which the wiring WWL is connected to the second gate electrode BGE of the transistor VT2 and the wiring BGL is connected to the first gate electrode TGE of the transistor VT2 in the structure in FIG. 5A. A memory cell 10B illustrated in FIG. 5C has a structure in which the wiring SL is connected to the lower electrode BSD of the transistor VT1 and the wiring RBL is connected to the upper electrode TSD of the transistor VT1 in the structure in FIG. 5A.

In one embodiment of the present invention, a potential that controls the electrical characteristics, specifically, the threshold voltage, of the transistor is supplied to the conductive layer functioning as the first gate electrode or the second gate electrode of the vertical transistor. This structure allows different potentials to be supplied to each transistor in accordance with the write operation, the retention operation, or the read operation, so that the electrical characteristics of the transistor can be controlled. In addition, the parasitic capacitances of the wirings can be different in the structures illustrated in FIGS. 5A to 5C.

For example, in the vertical transistor illustrated in FIG. 4A, the parasitic capacitance between the first gate electrode TGE and the upper electrode TSD is larger than the parasitic capacitance between the first gate electrode TGE and the lower electrode BSD. Thus, power consumption required for charging and discharging of the wirings can be reduced when the wiring RBL for data reading is positioned on the lower electrode BSD side as illustrated in FIG. 5A.

For example, in the vertical transistor illustrated in FIG. 4A, the parasitic capacitance of the first gate electrode TGE is larger than the parasitic capacitance of the second gate electrode BGE. Thus, power consumption required for charging and discharging of the wirings can be reduced when the wiring WWL for controlling the on and off states of the transistor VT2 is positioned on the second gate electrode BGE side as illustrated in FIG. 5B.

For example, in the vertical transistor illustrated in FIG. 4A, the wiring SL supplying a constant potential is positioned on the lower electrode BSD side, whereby the influence of noise of the wirings in a lower layer of the vertical transistor can be reduced.

With the structures illustrated in FIGS. 5A to 5C, a memory device having reduced power consumption, increased operation speed, reduced size, or increased memory capacity can be obtained.

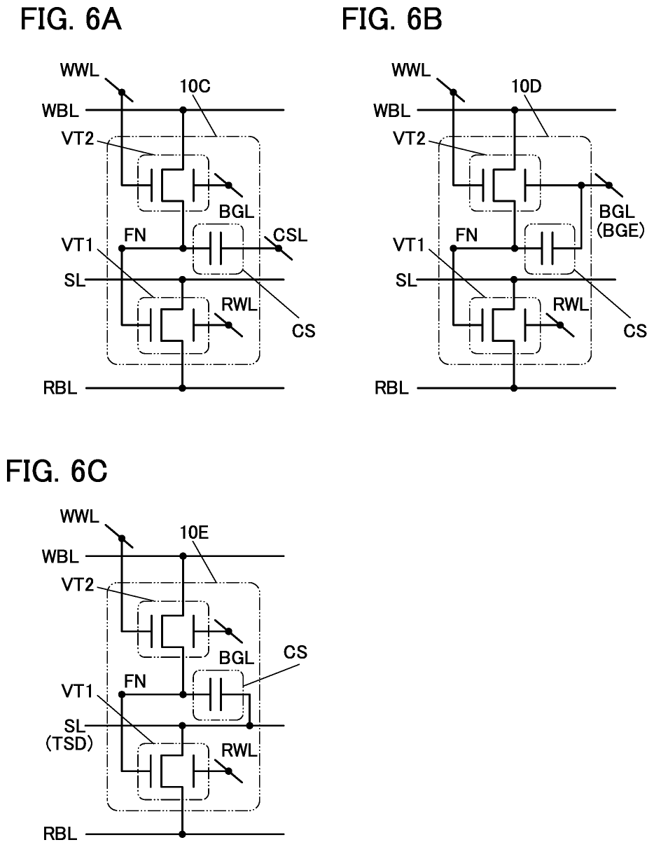

In the memory cell 10 illustrated in FIG. 5A, a capacitor for retaining a data potential is preferably connected to the node FN. FIG. 6A is a diagram illustrating a structure example of a memory cell 10C including a capacitor that can be used as the memory cells 10_1 to 10_3 described with reference to FIG. 1A.

The memory cell 10C illustrated in FIG. 6A includes a capacitor CS in addition to the components illustrated in FIG. 5A. One terminal of the capacitor CS is connected to the node FN. The other terminal of the capacitor CS is connected to a wiring CSL. The wiring CSL is supplied with a constant potential for retaining a potential of the node FN.

Note that the structure of the memory cell including the capacitor described with reference to FIG. 6A is not limited to the structure in FIG. 6A. For example, the structure in FIG. 6B or FIG. 6C may be employed. A memory cell 10D illustrated in FIG. 6B has a structure in which the other terminal of the capacitor CS is connected to the second gate electrode BGE of the transistor VT2, i.e., the wiring BGL, in the structure in FIG. 6A. The wiring BGL is supplied with a constant potential in a period in which data is the retained and a period in which data is read, whereby the capacitor CS can retain a data potential of the node FN. A memory cell 10E illustrated in FIG. 6C has a structure in which the other terminal of the capacitor CS is connected to the upper electrode TSD of the transistor VT1, i.e., the wiring SL, in the structure in FIG. 6A. The wiring SL is supplied with a constant potential, whereby the capacitor CS can retain a data potential of the node FN.

In one embodiment of the present invention, a potential that controls the electrical characteristics, specifically, the threshold voltage, of the transistor is supplied to the conductive layer functioning as the first gate electrode or the second gate electrode of the vertical transistor. This structure allows different potentials to be supplied to each transistor in accordance with the write operation, the retention operation, or the read operation, so that the electrical characteristics of the transistor can be controlled. In addition, the structures illustrated in FIGS. 6A to 6C can increase the electric charge retention characteristics of the node FN owing to the capacitor CS. For example, it is possible to reduce the influence of a change in a potential due to noise or the like and a change in a potential caused when a word signal supplied to the wiring WWL changes between an H level and an L level. With this structure, a memory device having reduced power consumption, increased operation speed, reduced size, or increased memory capacity can be obtained.

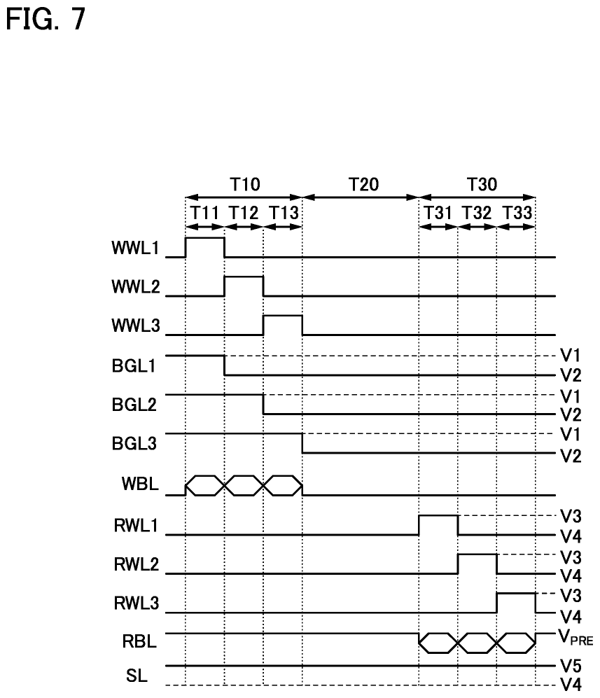

FIG. 7 is a diagram showing a modification example of a timing chart showing operation of the memory cells 10_1 to 10_3 described with reference to FIG. 1B. FIG. 7 is different from the timing chart in FIG. 1B in that each of the control signals of the wirings BGL_1 to BGL_3 is set to an H level in a period before data writing and set to an L level in a period after data writing.

In one embodiment of the present invention, a potential that controls the electrical characteristics, specifically, the threshold voltage, of the transistor is supplied to the conductive layer functioning as the first gate electrode or the second gate electrode of the vertical transistor. This structure allows different potentials to be supplied to each transistor in accordance with the write operation, the retention operation, or the read operation, so that the electrical characteristics of the transistor can be controlled. Additionally, in the structure shown in FIG. 7, data writing can be controlled without changing a control signal of the wiring BGL in accordance with the timing at which the word signal, which is supplied to the wiring WWL, rises (changes from an L level to an H level). With this structure, a memory device having reduced power consumption, increased operation speed, reduced size, or increased memory capacity can be obtained.

In the transistor in the memory device of one embodiment of the present invention, a material exhibiting ferroelectricity can be used for, for example, the insulating layers illustrated in FIG. 3A (e.g., the insulating layers 160 and 170) or an insulating layer included in the capacitor CS illustrated in FIG. 6A.

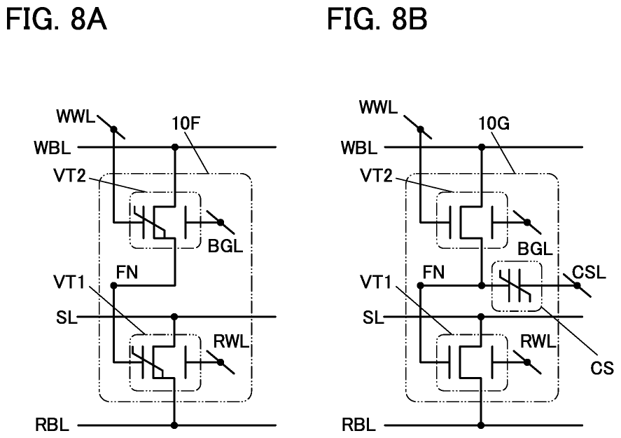

FIG. 8A illustrates an example of a circuit diagram of a memory cell 10F in which a material exhibiting ferroelectricity is used for the insulating layer 160 among the insulating layers illustrated in FIG. 3A.

Examples of the material exhibiting ferroelectricity include oxides such as hafnium oxide, zirconium oxide, and hafnium zirconium oxide. A material obtained by adding a Group 3 element to the oxide is preferably used. For example, the oxide preferably contains at least one of scandium, yttrium, and an element belonging to lanthanoid. In particular, yttrium, lanthanum, or scandium is preferable because it is relatively easy to handle and has high compatibility with a semiconductor manufacturing process. When such an element is added, not only stable ferroelectricity can be exhibited but also degradation of characteristics caused by rewriting repeatedly can be inhibited, so that reliability can be improved. For example, the element is preferably added at higher than or equal to 0.5 at % and lower than or equal to 10 at %. Other examples of the additive element include silicon, aluminum, gadolinium, and scandium.

An oxide containing one or both of hafnium and zirconium exhibits ferroelectricity easily even when it is used in an extremely thin film formed by a formation method of a thin film, such as a sputtering method or an atomic layer deposition (ALD) method, and thus the oxide has high compatibility with a semiconductor manufacturing process and can reduce the manufacturing cost.

FIG. 8B illustrates an example of a circuit diagram of a memory cell 10G in which a material exhibiting ferroelectricity is used for the insulating layer included in the capacitor CS illustrated in FIG. 6A. The capacitor CS including the material exhibiting ferroelectricity is referred to as a ferroelectric capacitor in some cases.

The structures illustrated in FIGS. 8A and 8B enable the memory device of one embodiment of the present invention to perform non-destructive reading, operate at a low voltage (writing and reading), and have extremely high rewrite endurance.

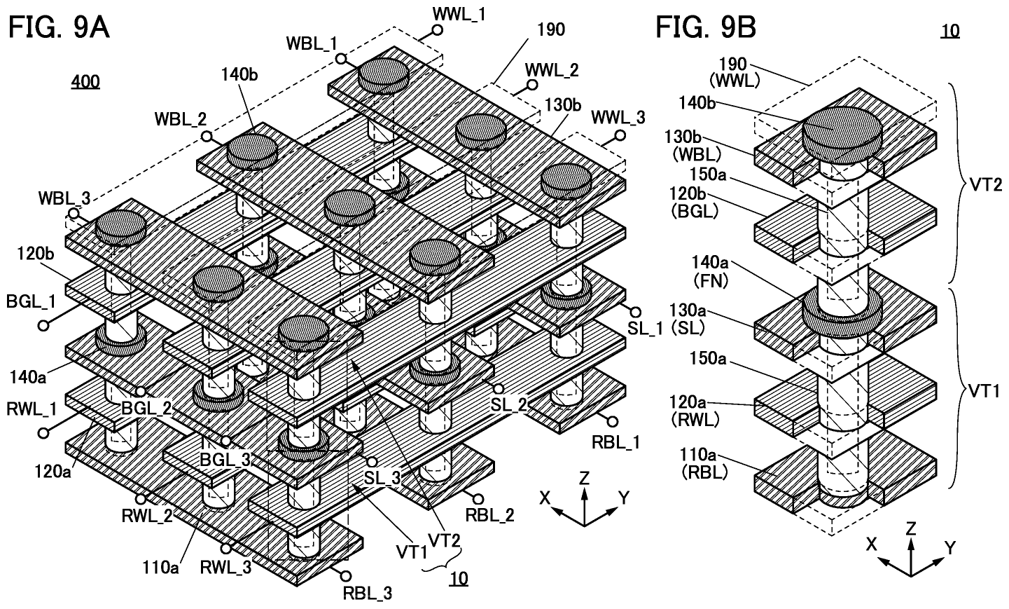

FIGS. 9A and 9B illustrate a structure example of the memory cell 10 of a two-transistor NOSRAM and a structure example of a memory array 400 including the memory cell. FIG. 9A is an example of a perspective view of the memory array 400 in which a plurality of memory cells 10 each including the transistor VT1 and the transistor VT2 that are stacked are arranged side by side. The transistor VT1 and the transistor VT2 are vertical transistors. The memory cell 10 is connected to a conductive layer 110a, a conductive layer 120a, a conductive layer 130a, a conductive layer 140a, a conductive layer 120b, a conductive layer 130b, a conductive layer 140b, and a conductive layer 190. Note that for clarity, in FIG. 9A, insulating layers such as interlayer films are not illustrated, and the uppermost conductive layers 190 are illustrated by dashed lines.

The conductive layers 110a illustrated in FIG. 9A function as the wirings RBL (typically, the wirings RBL_1 to RBL_3 are illustrated) illustrated in FIG. 1A and the like. The conductive layers 120a illustrated in FIG. 9A function as the wirings RWL (typically, the wirings RWL_1 to RWL_3 are illustrated) illustrated in FIG. 1A and the like. The conductive layers 130a illustrated in FIG. 9A function as the wirings SL (typically, the wirings SL_1 to SL_3 are illustrated) illustrated in FIG. 1A and the like. The conductive layers 120b illustrated in FIG. 9A function as the wirings BGL (typically, the wirings BGL_1 to BGL_3 are illustrated) illustrated in FIG. 1A and the like. The conductive layers 130b illustrated in FIG. 9A function as the wirings WBL (typically, the wirings WBL_1 to WBL_3 are illustrated) illustrated in FIG. 1A and the like. The conductive layers 190 and the conductive layers 140b connected to the conductive layers 190 function as the wirings WWL (typically, the wirings WWL_1 to WWL_3 are illustrated) illustrated in FIG. 1A and the like.

Although FIG. 9A illustrates an example in which the memory cells 10 are arranged at regular intervals in the X direction and the Y direction, a staggered arrangement in which the memory cells 10 are alternately staggered one by one may be employed. Although FIG. 9A illustrates an example in which the wirings are provided to be orthogonal to each other in the X direction and the Y direction, the wirings may be provided to be in a direction not orthogonal to each other.

Next, a structure example of the memory cell 10 will be described. FIG. 9B is a perspective view illustrating the structure example of the memory cell 10. As illustrated in FIG. 9B, the transistor VT1 includes the conductive layer 110a, the conductive layer 120a, the conductive layer 130a, the conductive layer 140a, and an oxide semiconductor layer 150a as components. The transistor VT2 includes the conductive layer 140a, the conductive layer 120b, the conductive layer 130b, the conductive layer 140b, and the oxide semiconductor layer 150a. The transistor VT2 may include the conductive layer 190.

Note that for clarity, in FIG. 9B, insulating layers such as interlayer films are not illustrated, and part of the conductive layer 110a, part of the conductive layer 120a, part of the conductive layer 130a, part of the conductive layer 120b, part of the conductive layer 130b, and the conductive layer 190 are illustrated by dashed lines.

In the memory cell 10 illustrated in FIG. 9B, the conductive layer 110a includes a region overlapping with the conductive layers 120a, 130a, 140a, 120b, 130b, and 140b in the perpendicular direction (Z direction). Note that a cross-sectional view refers to viewing from the normal direction of the perpendicular direction and corresponds to a cross-sectional diagram taken along a plane parallel to the perpendicular direction.

The structures illustrated in FIGS. 9A and 9B each include a region where the conductive layers 110a, 120a, 130a, 140a, 120b, 130b, and 140b included in the memory cell 10 overlap with one another. Although this might cause operation to be unstable due to electric interference between transistors or conductive layers, one embodiment of the present invention can have a structure in which a potential that controls the electrical characteristics, specifically, the threshold voltage, of the transistor is supplied to the conductive layer functioning as the first gate electrode or the second gate electrode of the vertical transistor. This structure allows different potentials to be supplied to each transistor in accordance with the write operation, the retention operation, or the read operation, so that the electrical characteristics of the transistor can be controlled. With this structure, a memory device having reduced power consumption, increased operation speed, reduced size, or increased memory capacity can be obtained.

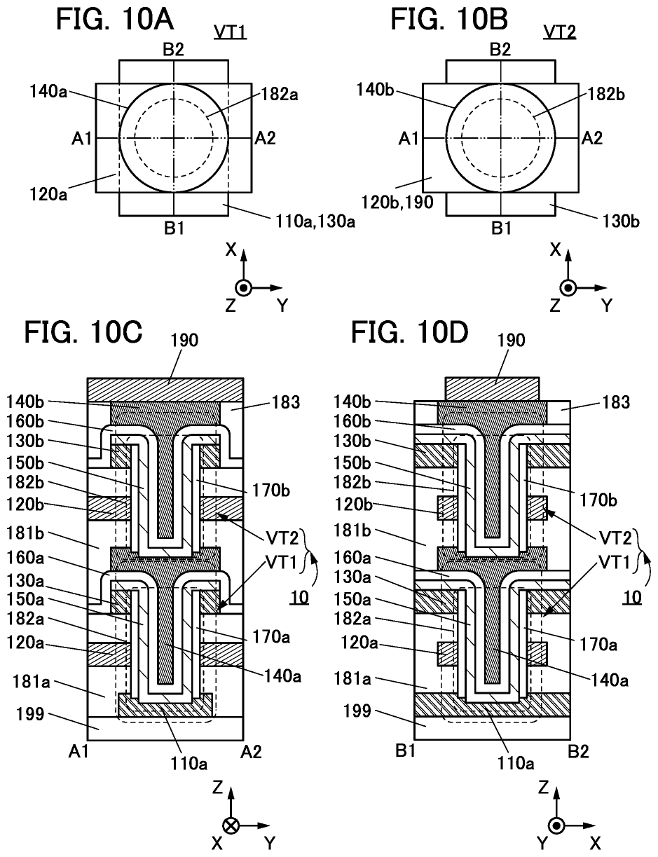

Structure examples of the transistors VT1 and VT2 included in the memory cell 10 illustrated in FIG. 9B will be described with reference to FIGS. 10A to 10D. FIG. 10A is a plan view of the transistor VT1, and FIG. 10B is a plan view of the transistor VT2. In the plan views, some components are not illustrated for clarity.

FIG. 10C is a diagram corresponding to a cross section along a line segment A1-A2 in FIGS. 10A and 10B. FIG. 10D is diagram corresponding to a cross section along a line segment B1-B2 in FIGS. 10A and 10B.

The memory cell 10 includes an insulating layer 199 over a substrate (not illustrated), the transistor VT1 over the insulating layer 199, and the transistor VT2 over the transistor VT1. Between the transistors and wirings, an insulating layer 181a, an insulating layer 181b, the insulating layer 183, and the like functioning as interlayer films can be provided.

The transistor VT1 includes the conductive layer 110a, the conductive layer 120a, the conductive layer 130a, the conductive layer 140a, the oxide semiconductor layer 150a, an insulating layer 160a, and an insulating layer 170a. In the transistor VT1, the oxide semiconductor layer 150a functions as a semiconductor layer. The conductive layer 140a functions as the first gate electrode. The insulating layer 160a functions as a first gate insulating film. The conductive layer 120a functions as the second gate electrode. The insulating layer 170a functions as a second gate insulating film. The conductive layers 110a and 130a function as a source electrode and a drain electrode.

The transistor VT2 includes the conductive layer 140a, the conductive layer 120b, the conductive layer 130b, the conductive layer 140b, an oxide semiconductor layer 150b, an insulating layer 160b, and an insulating layer 170b. In the transistor VT2, the oxide semiconductor layer 150b functions as a semiconductor layer. The conductive layer 140b functions as the first gate electrode. The insulating layer 160b functions as the first gate insulating film. The conductive layer 120b functions as the second gate electrode. The insulating layer 170b functions as the second gate insulating film. The conductive layers 140a and 130b function as a source electrode and a drain electrode.

In other words, each of the structures of the transistors VT1 and VT2 corresponds to that of the transistor VT illustrated in FIG. 3A. Thus, in drawings, the corresponding components in the transistors VT, VT1, and VT2 are basically denoted by the same three-digit reference numerals. Unless otherwise specified, the description for the transistor VT can be referred to for the transistors VT1 and VT2.

Note that the conductive layer 140a in the transistor VT2 corresponds to the conductive layer 110a in the transistor VT1. In other words, the conductive layer 140a includes a region shared by the first gate electrode of the transistor VT1 and the one of the source electrode and the drain electrode of the transistor VT2.

In the transistor VT1, the oxide semiconductor layer 150a is provided in an opening portion 182a provided in the conductive layers 130a and 120a. In the opening portion 182a, the oxide semiconductor layer 150a includes a region overlapping with the conductive layer 140a with the insulating layer 160a therebetween and a region overlapping with the conductive layer 120a with the insulating layer 170a therebetween in the horizontal direction (the direction parallel to the X-Y plane). The oxide semiconductor layer 150a is in contact with the top surfaces of the conductive layers 130a and 110a. Note that a plan view refers to viewing from the normal direction of the horizontal direction and corresponds to a cross-sectional diagram taken along a plane parallel to the horizontal direction.

In the transistor VT2, the oxide semiconductor layer 150b is provided in an opening portion 182b provided in the conductive layers 130b and 120b. In the opening portion 182b, the oxide semiconductor layer 150b includes a region overlapping with the conductive layer 140b with the insulating layer 160b therebetween and a region overlapping with the conductive layer 120b with the insulating layer 170b therebetween in the horizontal direction (the direction parallel to the X-Y plane). The oxide semiconductor layer 150b is in contact with the top surfaces of the conductive layers 130b and 140a.

That is, in the structures illustrated in FIGS. 10C and 10D, the oxide semiconductor layer 150a can be surrounded by the conductive layers 120a and 140a with the insulating layers 160a and 170a therebetween in the horizontal direction, and the oxide semiconductor layer 150b can be surrounded by the conductive layers 120b and 140b with the insulating layers 160b and 170b therebetween in the horizontal direction. Thus, one embodiment of the present invention can have a structure in which a potential that controls the electrical characteristics, specifically, the threshold voltage, of the transistor is supplied to the conductive layer functioning as the first gate electrode or the second gate electrode of the vertical transistor. This structure allows different potentials to be supplied to each transistor in accordance with the write operation, the retention operation, or the read operation, so that the electrical characteristics of the transistor can be controlled. With this structure, a memory device having reduced power consumption, increased operation speed, reduced size, or increased memory capacity can be obtained.

The conductive layer 140b is connected to the conductive layer 190 formed over the conductive layer 140b. Note that the conductive layers 140b and 190 may be formed as the same component.

The top surface shapes of the conductive layers 140a and 140b are preferably substantially circular. Such structures enable high integration of the memory cells 10.

In order to increase the area where the transistor VT2 and the transistor VT1 overlap with each other, the top surface shape of the opening portion 182b is preferably the same as or similar to the top surface shape of the opening portion 182a where the transistor VT1 is formed.

Materials that can be used for the memory device are described below.

As a substrate that can be used for the memory device, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include any of the above semiconductor substrates including an insulator region, e.g., a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided over the substrate include a capacitor, a resistor, a switching element, a light-emitting element, and a memory element.

Examples of an insulator include an insulating oxide, an insulating nitride, an insulating oxynitride, an insulating nitride oxide, an insulating metal oxide, an insulating metal oxynitride, and an insulating metal nitride oxide.

With miniaturization and high integration of a transistor, for example, a problem such as generation of a leakage current may arise because of a thin gate insulator. When a high-k material is used for the insulator functioning as a gate insulator, the voltage at the time of operation of the transistor can be reduced while the physical thickness is maintained. In addition, the equivalent oxide thickness (EOT) of the insulator functioning as the gate insulator can be reduced. By contrast, when a low-dielectric-constant material is used for the insulator functioning as an interlayer film, the capacitance value of parasitic capacitance generated between wirings can be reduced. Thus, a material is preferably selected depending on the function of an insulator. Note that a material with a low dielectric constant is a material with high dielectric strength.

Examples of a material with a high dielectric constant (a high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides may contain nitrogen.

A transistor using an oxide semiconductor can have stable electrical characteristics when surrounded by an insulator having a function of inhibiting transmission of impurities and oxygen. The insulator having a function of inhibiting transmission of impurities and oxygen can have, for example, a single-layer structure or a stacked-layer structure of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting transmission of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

An insulating layer that is in contact with a semiconductor layer or provided in the vicinity of the semiconductor layer, such as a gate insulating film, preferably includes a region containing excess oxygen. For example, when an insulating layer including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide.

Examples of the insulator having a barrier property against oxygen include an oxide containing one or both of aluminum and hafnium, an oxide containing hafnium and silicon (hafnium silicate), magnesium oxide, gallium oxide, gallium zinc oxide, silicon nitride, and silicon nitride oxide. Examples of an oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, indium gallium zinc oxide, silicon nitride, and silicon nitride oxide.

An insulator having a barrier property against oxygen and an insulator having a barrier property against hydrogen can each be regarded as an insulator having a barrier property against one or both of oxygen and hydrogen.

Examples of an insulator having a function of capturing or fixing hydrogen include an oxide containing magnesium and an oxide containing one or both of aluminum and hafnium. These oxides preferably have an amorphous structure. In such an oxide having an amorphous structure, an oxygen atom has a dangling bond, and the oxide has a property of capturing or fixing hydrogen with the dangling bond in some cases. Although these metal oxides preferably have an amorphous structure, a crystal region may be partly formed.

Note that in this specification and the like, a barrier insulating film refers to an insulating film having a barrier property. In addition, the barrier property refers to a property that does not easily allow diffusion of a target substance (also referred to as a property that does not easily allow passage of a target substance, a property with low permeability of a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom, an oxygen molecule, and the like. Specifically, a barrier property against oxygen refers to a property that does not easily allow diffusion of at least one of an oxygen atom, an oxygen molecule, and the like.

For the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, tantalum nitride, titanium nitride, tungsten nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. As examples of the conductive material containing oxygen, indium oxide containing tungsten oxide, indium oxide containing titanium oxide, indium tin oxide, indium tin oxide containing titanium oxide, indium tin oxide containing silicon, indium zinc oxide, indium zinc oxide containing tungsten oxide, and the like can be given. In this specification and the like, a conductive film formed using the conductive material containing oxygen may be referred to as an oxide conductive film.

In addition, a conductive material containing tungsten, copper, or aluminum as its main component is preferable because it has high conductivity.

Conductive layers formed using any of the above materials may be stacked. For example, a stacked-layer structure combining a material containing the above metal element and a conductive material containing oxygen may be employed. Alternatively, a stacked-layer structure combining a material containing the above metal element and a conductive material containing nitrogen may be employed. Further alternatively, a stacked-layer structure combining a material containing the above metal element, a conductive material containing oxygen, and a conductive material containing nitrogen may be employed.

In the case where an oxide semiconductor is used for the channel formation region of the transistor, the conductor functioning as the gate electrode (the first gate electrode or the second gate electrode) preferably employs a stacked-layer structure combining a material containing the above metal element and a conductive material containing oxygen. In this case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in an oxide semiconductor where the channel is formed. A conductive material containing any of the above metal elements and nitrogen may also be used. For example, a conductive material containing nitrogen, such as titanium nitride or tantalum nitride, may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide containing silicon may be used. Indium gallium zinc oxide containing nitrogen may be used. With the use of such a material, hydrogen contained in the oxide semiconductor where the channel is formed can be captured in some cases. Hydrogen entered from a surrounding insulator or the like can also be captured in some cases.

A semiconductor material that can be used for the semiconductor layer is not limited to an oxide semiconductor. A semiconductor material which has a band gap (a semiconductor material that is not a zero-gap semiconductor) can be used for the semiconductor layer. For example, a single element semiconductor, a compound semiconductor, a layered material (also referred to as an atomic layered material or a two-dimensional material), or the like is preferably used as the semiconductor material.

In this specification and the like, the layered material is a group of materials having a layered crystal structure. In the layered crystal structure, layers formed by covalent bonding or ionic bonding are stacked with bonding such as the Van der Waals force, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron nitride that can be used for the semiconductor layer preferably includes a crystal with a cubic structure.

Examples of the layered material include graphene, silicene, boron carbonitride, and chalcogenide. Boron carbonitride serving as the layered material contains carbon, nitrogen, and boron atoms arranged in a hexagonal lattice structure on a plane. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

As the semiconductor layer, a transition metal chalcogenide functioning as a semiconductor is preferably used, for example. Specific examples of the transition metal chalcogenide which can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a memory device with a high on-state current to be provided.

In one embodiment of the present invention, a potential that controls the electrical characteristics, specifically, the threshold voltage, of the transistor is supplied to the conductive layer functioning as the first gate electrode or the second gate electrode of the vertical transistor. This structure allows different potentials to be supplied to each transistor in accordance with the write operation, the retention operation, or the read operation, so that the electrical characteristics of the transistor can be controlled. With this structure, a memory device having reduced power consumption, increased operation speed, reduced size, or increased memory capacity can be obtained.

The configurations, structures, methods, and the like described in this embodiment can be used in an appropriate combination with any of the configurations, structures, methods, and the like described in the other embodiments and the like.

### Embodiment 2

In this embodiment, an oxide semiconductor layer can be used for a semiconductor layer of a transistor will be described.

[Oxide Semiconductor Layer]

The oxide semiconductor layer of one embodiment of the present invention preferably includes a metal oxide layer having crystallinity. Examples of the structure of a metal oxide having crystallinity include a c-axis aligned crystalline (CAAC) structure, a polycrystalline structure, and a nano-crystal (nc) structure. By using a metal oxide layer having crystallinity as the oxide semiconductor layer, the density of defect states in the oxide semiconductor layer can be reduced. Thus, the reliability of a transistor including the oxide semiconductor layer of one embodiment of the present invention can be enhanced, and the reliability of a memory device including the transistor can be enhanced.

The oxide semiconductor layer of one embodiment of the present invention preferably includes a metal oxide having a CAAC structure, in particular. Note that the CAAC structure is a crystal structure in which a plurality of microcrystals (typically, a plurality of microcrystals having a hexagonal crystal structure) have c-axis alignment and are connected on the a-b plane without alignment. In cross-sectional observation of an oxide semiconductor layer having a CAAC structure with use of a high-resolution transmission electron microscope (TEM) image, metal atoms are observed to be arranged in a layered manner in a crystal part. Thus, the oxide semiconductor layer having the CAAC structure can also be regarded as having a structure including the layered crystal part.

The crystallinity of the oxide semiconductor layer can be analyzed by X-ray diffraction (XRD), TEM, or electron diffraction (ED), for example. Alternatively, these methods may be combined as appropriate for analysis.

Note that there is no particular limitation on the crystallinity of a semiconductor material included in the oxide semiconductor layer. For example, at least one of an amorphous semiconductor (a semiconductor having an amorphous structure), a single crystal semiconductor (a semiconductor having a single crystal structure), and a semiconductor having other crystallinity than single crystal (a microcrystalline semiconductor, a polycrystalline semiconductor, or a semiconductor partly including crystal regions) may be included. The oxide semiconductor layer having crystallinity can inhibit deterioration of the transistor characteristics in some cases.

Examples of the metal oxide included in the oxide semiconductor layer of one embodiment of the present invention include indium oxide, gallium oxide, and zinc oxide. The metal oxide of one embodiment of the present invention preferably contains at least indium (In) or zinc (Zn). The metal oxide preferably contains two or three selected from indium, an element M, and zinc. The element M is a metal element or metalloid element that has a high bonding energy with oxygen, such as a metal element or metalloid element whose bonding energy with oxygen is higher than that of In. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, still further preferably gallium. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal clement” in this specification and the like may refer to a metalloid element.

Examples of the metal oxide of one embodiment of the present invention include indium zinc oxide (also referred to as In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide, IGTO), gallium zinc oxide (also referred to as Ga-Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO). Alternatively, indium tin oxide containing silicon (also referred to as ITSO), gallium tin oxide (Ga—Sn oxide), aluminum tin oxide (Al—Sn oxide), or the like can be given.

By increasing the proportion of the number of indium atoms in the total number of atoms of all the metal elements included in the metal oxide, a high on-state current and high frequency characteristics of the transistor can be achieved.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include Period 5 metal elements and Period 6 metal elements. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, changes in electrical characteristics of the transistor are reduced and the transistor can have high reliability.

By increasing the proportion of the element M atoms in the sum of atoms of all metal elements included in the metal oxide, oxygen vacancies can be prevented from being formed in the metal oxide. Accordingly, generation of carriers due to oxygen vacancies is inhibited, which reduces the off-state current of the transistor. Furthermore, changes in electrical characteristics of the transistor are reduced and the transistor can have high reliability.

In the description of this embodiment, In—Ga—Zn oxide is sometimes given as an example of the metal oxide.

The oxide semiconductor layer of one embodiment of the present invention has crystallinity. The oxide semiconductor layer of one embodiment of the present invention preferably has a CAAC structure.

The oxide semiconductor layer of one embodiment of the present invention can be obtained by forming metal oxides by at least two kinds of formation methods. For example, the oxide semiconductor layer of one embodiment of the present invention can be obtained by forming metal oxides by a first formation method and a second formation method. The oxide semiconductor layer obtained by at least two kinds of formation methods may be referred to as a hybrid OS.

The oxide semiconductor layer of one embodiment of the present invention can be formed in the following manner: a metal oxide is formed as a first layer by a first formation method, and then a metal oxide is formed as a second layer over the first layer by a second formation method. In that case, the first formation method preferably causes less damage to a formation surface than the second formation method. When a formation method that causes less damage to a formation surface is used as the first formation method, formation of a mixed layer at an interface between the oxide semiconductor layer and a layer that is the formation surface of the oxide semiconductor layer can be inhibited. Moreover, entry of impurities such as silicon into the second layer can be inhibited, so that the crystallinity of the oxide semiconductor layer can be increased.

Examples of the first formation method include an atomic layer deposition (ALD) method, a chemical vapor deposition (CVD) method, a molecular beam epitaxy (MBE) method, and a wet process. Examples of the CVD method include a plasma enhanced CVD (PECVD) method, a thermal CVD method, a photo CVD method, and a metal organic CVD (MOCVD) method. Examples of the wet process include a spray coating method. Each of the ALD method and the CVD method is suitable as the first formation method because it can inhibit damage to the formation surface as compared with a sputtering method described later.

Examples of the ALD method include a thermal ALD method, in which a precursor and a reactant react with each other only by a thermal energy, and a plasma-enhanced ALD (PEALD) method, in which a reactant excited by plasma is used.

The ALD method enables deposition of one-by-one atomic layer, and has various advantages such as formation of an extremely thin film, deposition on a component with a high aspect ratio, deposition on a surface having a large step, formation of a film with few defects such as pinholes, deposition with excellent coverage, and low-temperature deposition. The PEALD method utilizing plasma may be preferred because deposition at lower temperature is possible.

Note that some precursors used in the ALD method contain an element such as carbon or chlorine. Thus, a film formed by the ALD method sometimes contains an element such as carbon or chlorine in a larger quantity than a film formed by another formation method. Note that element quantification can be performed by X-ray photoelectron spectroscopy (XPS) or secondary ion mass spectrometry (SIMS). The formation method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike in a formation method in which particles ejected from a target or the like are deposited, the ALD method is a formation method in which a film is formed by reaction at a surface of an object to be processed. Thus, the ALD method can provide good step coverage, almost regardless of the shape of an object. In particular, the ALD method allows excellent step coverage and excellent thickness uniformity and is suitable for covering a surface of an opening portion with a high aspect ratio, for example.

A high-quality film can be obtained at a relatively low temperature by a PECVD method. A thermal CVD method does not use plasma and thus can cause less plasma damage to an object. The thermal CVD method yields a film with few defects because of no plasma damage during deposition.

Examples of the second formation method include a sputtering method and a pulsed laser deposition (PLD) method. A metal oxide formed by the second formation method is likely to have a CAAC structure.

Note that a metal oxide having a microcrystalline structure or an amorphous structure that has lower crystallinity than the CAAC structure is sometimes formed as the first layer, for example. Formation of the second layer having high crystallinity on the first layer having low crystallinity or the formation of the second layer followed by heat treatment can increase the crystallinity of the first layer with the second layer as a nucleus in some cases. Accordingly, the crystallinity can be increased in the whole oxide semiconductor layer including the vicinity of the interface with the formation surface.

Furthermore, a third layer can be formed over the second layer. Because the second layer has high crystallinity, the third layer can grow with a crystal of the second layer as a nucleus or a seed. Thus, the third layer can be crystallized even when a formation method that easily gives crystallinity is not employed as the formation method of the third layer. Here, for example, when a formation method that gives higher coverage than that of the second layer is employed for formation of the third layer, the whole oxide semiconductor layer can have both high crystallinity and high coverage.

In an example, the oxide semiconductor layer of one embodiment of the present invention can be formed in the following manner: a metal oxide is formed as the first layer by the first formation method, a metal oxide is formed as the second layer by the second formation method, and a metal oxide is formed as the third layer by the first formation method. Specifically, an ALD method can be employed for the first formation method, and a sputtering method can be employed for the second formation method. The ALD method is a formation method that achieves higher coverage than a sputtering method, and when the ALD method is employed for the formation methods of the first layer and the third layer, the coverage with the oxide semiconductor layer can be improved. Thus, the oxide semiconductor layer can be formed to favorably cover a step, an opening portion, or the like with a high aspect ratio.

### [Formation Method of Oxide Semiconductor Layer]

For example, an oxide semiconductor 230 that is an oxide semiconductor layer can be formed in the following manner: an oxide semiconductor 230a is formed over a layer 229 that is a formation surface of the oxide semiconductor by an ALD method, an oxide semiconductor 230b is formed over the oxide semiconductor 230a by a sputtering method, and an oxide semiconductor 230c is formed over the oxide semiconductor 230b by an ALD method. Moreover, heat treatment is preferably performed after the formation of the oxide semiconductor 230. By performing the heat treatment, the crystallinity of the oxide semiconductor 230 can be increased. Here, the heat treatment is not limited to heating. For example, the heat treatment may be performed with heat applied in the manufacturing process.

The oxide semiconductor 230 can be used for the oxide semiconductor layer 150, for example. The layer 229 corresponds to the insulating layer 160, 170, or the like described in the above embodiment.

The layer 229 does not need to have crystallinity. In the case where the layer 229 has crystallinity, the layer 229 may have a crystal structure with low lattice matching with the metal oxide included in the oxide semiconductor 230.

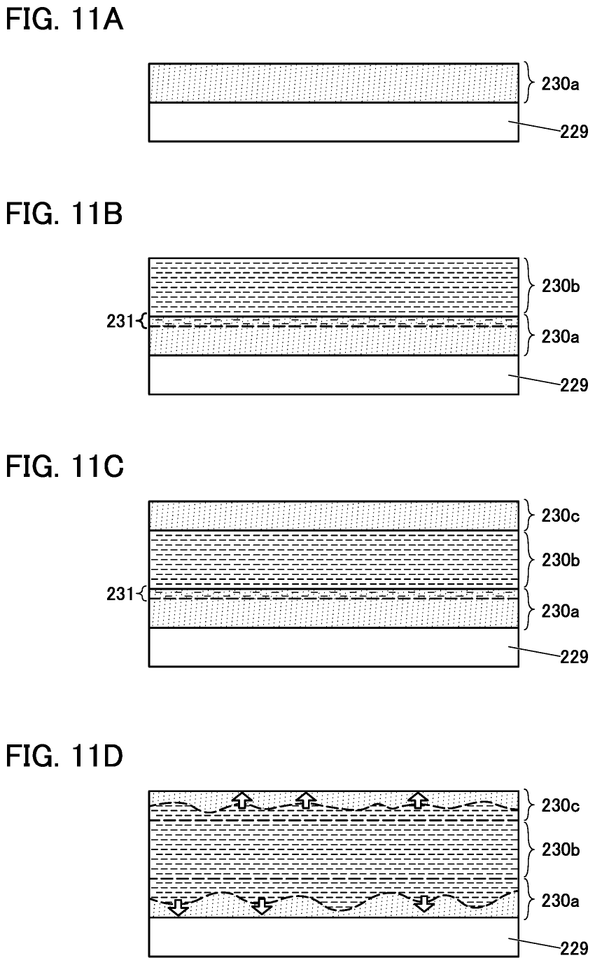

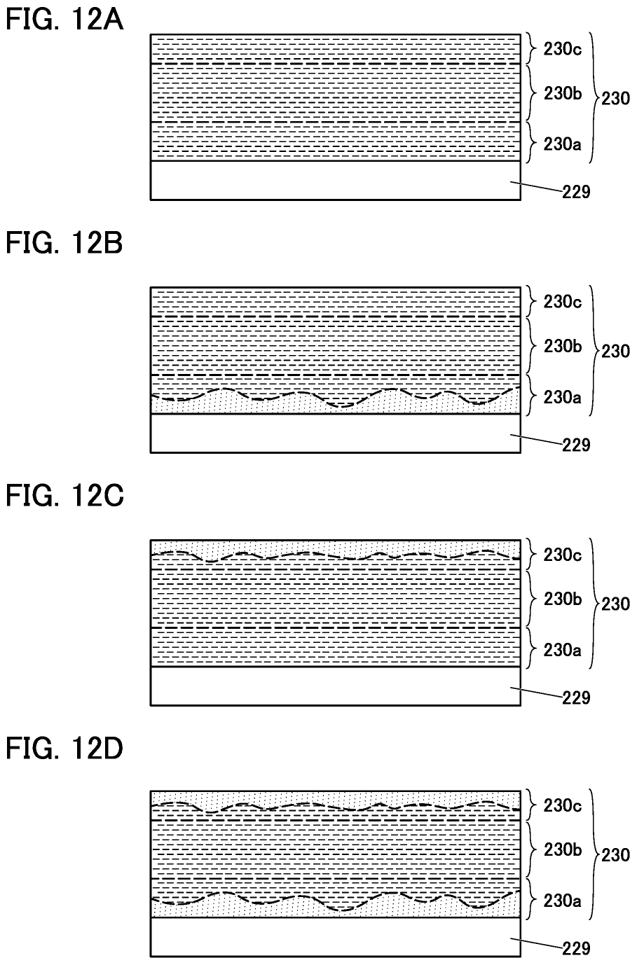

An example of a method for forming the oxide semiconductor 230 is described with reference to FIGS. 11A to 11D and FIGS. 12A to 12D.

In the case where the metal oxide film is deposited by a sputtering method, damage to the formation surface due to, for example, a sputtering particle or energy applied to the substrate side by a sputtering particle or the like may cause alloying of a component contained in the metal oxide film with a component contained in the layer serving as the formation surface. In the case where alloying occurs, it is difficult to increase the crystallinity of the alloyed region even when heat treatment described later is performed. When an oxide semiconductor layer including the alloyed region is used for a transistor, the initial characteristics or reliability of the transistor may be adversely affected. Therefore, it is preferable to inhibit alloying of the component contained in the metal oxide film with the component contained in the layer serving as the formation surface.

Thus, the oxide semiconductor 230a is formed over the layer 229 by an ALD method first (FIG. 11A). Next, the oxide semiconductor 230b is formed over the oxide semiconductor 230a by a sputtering method (FIG. 11B).

In the method for forming the oxide semiconductor layer of one embodiment of the present invention, the oxide semiconductor 230a is formed between the oxide semiconductor 230b and the layer 229 by a formation method that causes less damage to the formation surface; thus, the alloying of the component contained in the oxide semiconductor 230 with the component contained in the layer 229 can be inhibited, so that the crystallinity of the oxide semiconductor 230 can be further increased.

The above structure can reduce the thickness of the alloyed region or reduce the thickness of the alloyed region to the extent that the alloyed region cannot be observed. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 11A and 11B illustrate an example in which an alloyed region is not formed between the layer 229 and the oxide semiconductor 230a.

Furthermore, the thickness of the alloyed region can sometimes be obtained by composition analysis of the region and its vicinity with SIMS or energy dispersive X-ray spectroscopy (EDX) line analysis.

For example, EDX line analysis is performed on the region and its vicinity with the direction perpendicular to the formation surface of the oxide semiconductor 230a as the depth direction. Next, in profiles of quantitative values of elements in the depth direction obtained by the analysis, the depth at which the quantitative value of a metal that is the main component of the oxide semiconductor 230a and is not the main component of a layer (here, the layer 229) serving as a formation surface (the metal is In when the oxide semiconductor 230a contains In) becomes half is defined as a depth (position) of the interface between the region and the oxide semiconductor 230a. Furthermore, the depth at which the quantitative value of an element (e.g., Si) that is the main component of the layer serving as the formation surface and that is not the main component of the oxide semiconductor 230a becomes half is defined as a depth (position) of the interface between the region and the layer serving as the formation surface. In the above manner, the thickness of the alloyed region can be calculated.

When the thickness of the alloyed region in the oxide semiconductor layer of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, in the case where SIMS analysis of the oxide semiconductor 230 formed over the layer 229 that is formed using a silicon oxide layer is performed, the depth at which the silicon concentration is 50% of the maximum value of the silicon concentration of the layer 229 is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t_s2. The thickness t_s2 is preferably less than or equal to 3 nm, further preferably less than or equal to 2 nm.

When the thickness of the alloyed region is reduced, the thickness t_s2 can be a value within the above range.

Note that when the thickness of the alloyed region is reduced, the CAAC structure can be formed in the vicinity of the formation surface. Here, the vicinity of the formation surface refers to, for example, a region ranging from the formation surface of the oxide semiconductor 230 to greater than 0 nm and less than or equal to 3 nm, preferably greater than 0 nm and less than or equal to 2 nm, further preferably greater than or equal to 1 nm and less than or equal to 2 nm in a direction substantially perpendicular to the formation surface of the oxide semiconductor 230.

Note that the CAAC structure in the vicinity of the formation surface can be confirmed in TEM observation in some cases. For example, in high-resolution TEM cross-sectional observation of the oxide semiconductor 230, bright spots arranged in a layered manner in a direction parallel to the formation surface are observed in the vicinity of the formation surface.

Note that when the oxide semiconductor 230a is formed by an ALD method, an oxide semiconductor layer having a microcrystalline structure or an amorphous structure that has lower crystallinity than the CAAC structure may be formed. That is, in the formation step illustrated in FIG. 11A, the oxide semiconductor 230a sometimes includes a region having lower crystallinity than the oxide semiconductor 230b.

The oxide semiconductor 230b preferably has a composition suitable for forming the CAAC structure.

When the oxide semiconductor 230b is formed by a sputtering method, a mixed layer 231 is formed on the surface of the oxide semiconductor 230a or in the vicinity of the surface. A fine crystal region is sometimes formed in the mixed layer 231 by, for example, sputtered particles or energy or the like applied to the substrate side by sputtered particles or the like at the time of forming the oxide semiconductor 230b. In the subsequent heat treatment step, the mixed layer 231 or the fine crystal region formed in the mixed layer 231 serves as a nucleus, and at least part of the oxide semiconductor 230a is crystallized in some cases.

In the deposition of the oxide semiconductor 230b by a sputtering method, substrate heating is preferably performed. In forming a metal oxide, the substrate temperature (stage temperature) at the time of forming the metal oxide is increased, whereby a metal oxide with high crystallinity can be formed in some cases.

Next, the oxide semiconductor 230c is formed over the oxide semiconductor 230b by an ALD method (FIG. 11C). For the formation of the oxide semiconductor 230c by an ALD method, the method for forming the oxide semiconductor 230a can be referred to.

When the oxide semiconductor 230c is formed over the oxide semiconductor 230b having the CAAC structure by an ALD method, the oxide semiconductor 230c may epitaxially grow with the oxide semiconductor 230b as a nucleus. Thus, at the time of forming the oxide semiconductor 230c, the oxide semiconductor 230c may include a region having a CAAC structure. The region having the CAAC structure is preferably formed throughout the oxide semiconductor 230c.

Next, a heat treatment step may be performed. By the heat treatment step, the crystallinity of the region having the CAAC structure in the oxide semiconductor 230c is increased in some cases. In the case where the region is formed only below the oxide semiconductor 230c after deposition by an ALD method, the region may be extended upward by the heat treatment step (FIG. 11D). That is, by the heat treatment, the region having a CAAC structure is sometimes formed in the whole layer of the oxide semiconductor 230c.

At least part of the oxide semiconductor 230a preferably has a CAAC structure by the heat treatment step (FIG. 11D). The CAAC structure is expected to be easily generated when the mixed layer 231 formed in the oxide semiconductor 230a in the formation of the oxide semiconductor 230b becomes a nucleus or a seed. The oxide semiconductor 230a preferably has a large CAAC region, and the CAAC region preferably extends to the vicinity of the layer 229.

Since the CAAC region extends from the upper portion to the lower portion of the oxide semiconductor 230a, the CAAC region can extend to the vicinity of the layer 229, regardless of the material and crystallinity of the layer 229. For example, even when the layer 229 has an amorphous structure, the oxide semiconductor 230a having high crystallinity can be formed. Thus, the method for forming the oxide semiconductor layer of one embodiment of the present invention is suitable for the case where a layer serving as the formation surface has an amorphous structure, in particular.

FIGS. 11A to 11D are cross-sectional diagrams illustrating the formation method of a metal oxide of one embodiment of the present invention. FIGS. 11A to 11D can also be regarded as conceptual diagrams illustrating a deposition model of the metal oxide of one embodiment of the present invention. As illustrated in FIGS. 11A to 11D, the crystallinity of each of the oxide semiconductors 230a and 230c is increased with the oxide semiconductor 230b as a nucleus or a seed. Specifically, the crystallinity of the oxide semiconductor 230a may be increased at the time of depositing the oxide semiconductor 230b or by heat treatment after the deposition of the oxide semiconductor 230c. In addition, the crystallinity of the oxide semiconductor 230c may be increased at the time of depositing the oxide semiconductor 230c or by heat treatment after the deposition of the oxide semiconductor 230c. Note that the heat treatment has an assisting function of increasing the crystallinity.

As described above, in the method for forming a metal oxide of one embodiment of the present invention, the crystallinity of the oxide semiconductors (here, the oxide semiconductors 230a and 230c) above and below the oxide semiconductor 230b can be increased by using the oxide semiconductor 230b (i.e., CAAC) having high crystallinity as a nucleus or a seed. This can increase the crystallinity of the whole oxide semiconductor layer. In other words, the oxide semiconductor 230b serves as a nucleus or a seed to cause solid-phase growths of the oxide semiconductors above and below the oxide semiconductor 230b, so that the oxide semiconductor with high crystallinity can be formed. An oxide semiconductor formed by such a formation method, here, a CAAC film, may be referred to as an axial growth CAAC (Axial Growth CAAC or AG CAAC). Although FIGS. 12A to 12D each illustrate a structure including the oxide semiconductors 230a, 230b, and 230c, one embodiment of the present invention is not limited thereto. For example, a structure including the oxide semiconductors 230a and 230b can also have an AG CAAC.

The region having a CAAC structure preferably spreads in the whole layer of the oxide semiconductor 230. FIG. 12A illustrates a state where the oxide semiconductors 230a, 230b, and 230c are each crystallized. In this case, a boundary between the oxide semiconductor 230a and the oxide semiconductor 230b is not observed in some cases. In addition, a boundary between the oxide semiconductor 230b and the oxide semiconductor 230c is not observed in some cases. The oxide semiconductor 230 may be expressed as one layer where the interfaces are not clearly observed. The oxide semiconductor 230 may be expressed as a single layer in some cases.

Part of the oxide semiconductor 230a or part of the oxide semiconductor 230c is not crystallized in some cases. In addition, a region having crystallinity lower than that of the CAAC structure may be present in part of the oxide semiconductor 230a or part of the oxide semiconductor 230c. An example illustrated in FIG. 12B illustrates a state of the oxide semiconductor 230a where the vicinity of the interface between the oxide semiconductor 230a and the layer 229 is not crystallized or a region having crystallinity lower than that of the CAAC structure is present in the vicinity of the interface between the oxide semiconductor 230a and the layer 229. FIG. 12C illustrates a state where the vicinity of the surface of the oxide semiconductor 230c is not crystallized or a region having crystallinity lower than that of the CAAC structure is present in the vicinity of the surface of the oxide semiconductor 230c. FIG. 12D illustrates a state where the vicinity of the interface between the oxide semiconductor 230a and the layer 229 and the vicinity of the surface of the oxide semiconductor 230c are not crystallized or regions having crystallinity lower than that of the CAAC structure are present in the vicinity of the interface between the oxide semiconductor 230a and the layer 229 and in the vicinity of the surface of the oxide semiconductor 230c.

Increasing the crystallinity of the oxide semiconductor layer can inhibit an increase in the electric resistance of the semiconductor layer of a transistor including the oxide semiconductor layer or increase the initial characteristics (in particular, the on-state current) of the transistor, and thus a transistor suitable for high-speed operation can be expected. In addition, the reliability and the on current of the transistor can be improved.

The oxide semiconductor layer of one embodiment of the present invention has high crystallinity throughout the whole layer. Thus, in the oxide semiconductor 230, the boundaries between the stacked films of the oxide semiconductors 230a, 230b, and 230c are not observed in some cases. In particular, after heat treatment is performed, the boundaries between the stacked films are difficult to observe in some cases. Whether the boundaries between the stacked films are present can be checked with a cross-sectional TEM or a cross-sectional STEM, for example.

As described above, when a metal oxide with a high In content is used for a transistor, the field-effect mobility of the transistor can be increased. On the other hand, an oxide semiconductor with a high In content tends to be polycrystallized. The use of a metal oxide having a polycrystalline structure for a transistor adversely affects the initial characteristics or reliability of the transistor. Thus, when an oxide semiconductor with a high In content is used for one or both of the oxide semiconductors 230a and 230c, crystals reflecting crystal orientations included in the oxide semiconductor 230b are formed, so that one or both of the oxide semiconductors 230a and 230c can be inhibited from being polycrystallized.

It is preferable that crystals included in the oxide semiconductor 230b and crystals included in the oxide semiconductor 230a or 230c have a small lattice mismatch. Thus, the oxide semiconductor 230a or 230c can form crystals reflecting the orientation of crystals included in the oxide semiconductor 230b. In this case, for example, in high-resolution TEM cross-sectional observation of the oxide semiconductor 230, bright spots arranged in a layered manner in a direction parallel to the formation surface are observed in the oxide semiconductor 230a or 230c.

As long as crystals included in the oxide semiconductor 230b and crystals included in the oxide semiconductor 230a or 230c have a small lattice mismatch, there is no particular limitation on the crystal structure of the oxide semiconductor 230a or 230c. The crystal structure of the oxide semiconductor 230a or 230c may be any of a cubic crystal structure, a tetragonal crystal structure, an orthorhombic crystal structure, a hexagonal crystal structure, a monoclinic crystal structure, and a trigonal crystal structure.

### [Composition of Oxide Semiconductor Layer]

As described above, the oxide semiconductor 230b preferably has a composition suitable for forming the CAAC structure. The oxide semiconductor 230b can be formed by a sputtering method, for example. In addition, the oxide semiconductor 230b preferably contains zinc, for example. The oxide semiconductor 230b containing zinc can be a metal oxide having high crystallinity. The oxide semiconductor 230b preferably contains an element M in addition to zinc. When the oxide semiconductor 230b contains the element M, formation of oxygen vacancies in the metal oxide can be inhibited, for example. Thus, the reliability of the transistor including an oxide semiconductor layer can be improved. As the oxide semiconductor 230b, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a composition of In:M:Zn=1:1:0.5 [atomic ratio] or in the neighborhood thereof, a metal oxide with a composition of In:M:Zn=1:1:2 [atomic ratio] or in the neighborhood thereof, a metal oxide with a composition of In:M:Zn=4:2:3 [atomic ratio] or in the neighborhood thereof, a metal oxide with a composition of In:M:Zn=1:3:2 [atomic ratio] or in the neighborhood thereof, or a metal oxide with a composition of In:M:Zn=1:3:4 [atomic ratio] or in the neighborhood thereof may be specifically used. Note that the neighborhood of the atomic ratio includes ±30% of an intended atomic ratio. In this case, it is preferable to use one or more of gallium, aluminum, and tin as the element M.

The oxide semiconductor 230b may have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed. Examples of the composition include a composition of In:Ga:Zn=4:0.1:1 [atomic ratio] or in the neighborhood thereof and a composition of In:Ga:Zn=2:0.1:1 [atomic ratio] or in the neighborhood thereof. Other examples include a composition of In:Sn:Zn=4:0.1:1 [atomic ratio] or in the neighborhood thereof and a composition of In:Sn:Zn=2:0.1:1 [atomic ratio] or in the neighborhood thereof.

The oxide semiconductors 230a and 230c can be metal oxides with a high proportion of In. The oxide semiconductors 230a and 230c can each be formed by an ALD method, for example. In particular, a metal oxide in which the proportion of In is higher than that of the element M is preferably used. With the use of a metal oxide having a high proportion of In, the on-state current can be increased and the frequency characteristics can be enhanced in a transistor using an oxide semiconductor layer.

Alternatively, the oxide semiconductors 230a and 230c may each have a structure not containing the element M. For example, an In—Zn oxide may be used. Specifically, a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof can be used. Alternatively, indium oxide may be used. A structure containing a slight amount of the element M may be employed for the oxide semiconductors 230a and 230c. Examples of the composition include a composition of In:Ga:Zn=4:0.1:1 [atomic ratio] or in the neighborhood thereof, a composition of In:Ga:Zn=2:0.1:1 [atomic ratio] or in the neighborhood thereof, a composition of In:Sn:Zn=4:0.1:1 [atomic ratio] or in the neighborhood thereof, and a composition of In:Sn:Zn=2:0.1:1 [atomic ratio] or in the neighborhood thereof.

Note that when the composition of zinc in the oxide semiconductor is increased, the crystallinity of the oxide semiconductor can be increased. In particular, the oxide semiconductor 230a preferably contains zinc. For example, in the case where the oxide semiconductor 230a is formed by an ALD method and the oxide semiconductor 230b is formed by a sputtering method, zinc contained in the oxide semiconductor 230a is sometimes diffused into the oxide semiconductor 230b. Note that the diffusion can be caused in sputtering or in heat treatment after the sputtering. Crystallinity is expected to be improved when zinc is diffused from the oxide semiconductor 230a into the oxide semiconductor 230b. Alternatively, lateral growth of a crystal part having c-axis alignment occurs when zinc is diffused from the oxide semiconductor 230a into the oxide semiconductor 230b, which is expected to promote CAAC.

The oxide semiconductors 230a and 230c can each be a metal oxide having a higher proportion of In than that of the oxide semiconductor 230b.

For example, as the oxide semiconductors 230a and 230c, a metal oxide having a Ga proportion higher than that of the oxide semiconductor 230b can be used. For the oxide semiconductors 230a and 230c, it is preferable to use a metal oxide with a composition of In:Ga:Zn=1:1:1 [atomic ratio] or in the neighborhood thereof, a metal oxide with a composition of In:Ga:Zn=1:3:2 [atomic ratio] or in the neighborhood thereof, or a metal oxide with a composition of In:Ga:Zn=1:3:4 [atomic ratio] or in the neighborhood thereof. When the proportion of Ga is increased, the band gap of each of the oxide semiconductors 230a and 230c can be larger than that of the oxide semiconductor 230b in some cases, for example. Thus, the oxide semiconductor 230b is sandwiched between the oxide semiconductors 230a and 230c each having a wide band gap, and the oxide semiconductor 230b mainly functions as a current path (channel). When the oxide semiconductor 230b is sandwiched between the oxide semiconductors 230a and 230c, trap states at the interfaces with the oxide semiconductor 230b and the vicinity thereof can be reduced. Accordingly, a buried-channel transistor where a channel is away from the interface with an insulating layer can be achieved, whereby the field-effect mobility can be increased.

In the oxide semiconductor layer of one embodiment of the present invention, even in the case where a composition in which the CAAC structure is less likely to be formed in the formation of a single layer is used for the oxide semiconductors 230a and 230c, crystal growth occurs with the oxide semiconductor 230b as a nucleus, so that the whole oxide semiconductor layer including the oxide semiconductors 230a and 230c can have a CAAC structure. Alternatively, a CAAC structure can be formed in a region that includes the oxide semiconductor 230b and at least part of each of the oxide semiconductors 230a and 230c.

In particular, even in a composition where the proportion of In in the oxide semiconductors 230a and 230c is high, crystallinity suitable for a semiconductor layer of a transistor can be obtained. For the oxide semiconductor layer of one embodiment of the present invention, it is possible to attain higher on-state characteristics of the transistor by increasing the proportion of In and a higher reliability by employing a CAAC structure with high crystallinity at the same time.

Note that the composition of the oxide semiconductor 230a may be different from that of the oxide semiconductor 230c.

For each of the oxide semiconductors 230a and 230c, a metal oxide having the same composition as the oxide semiconductor 230b may be used.

With the use of the oxide semiconductor layer having a CAAC structure formed by the above two kinds of formation methods for a channel formation region of a transistor, the transistor can have excellent characteristics (e.g., a high on-state current, high field-effect mobility, a low S value, high frequency characteristics (also referred to as f characteristics), or high reliability).

Analysis of the composition of the metal oxide used for the oxide semiconductor 230 can be performed by energy dispersive X-ray spectrometry (EDX), XPS, inductively coupled plasma-mass spectrometry (ICP-MS), or inductively coupled plasma-atomic emission spectrometry (ICP-AES). Alternatively, these methods may be combined as appropriate for the analysis. As for an element whose content is low, the actual content may be different from the content obtained by analysis because of the influence of the analysis accuracy. In the case where the content of the element M is low, for example, the content of the element M obtained by analysis may be lower than the actual content.

### [C-Axis Alignment Proportion]

The oxide semiconductor layer of one embodiment of the present invention has a CAAC structure. The crystallinity degree of the oxide semiconductor layer of one embodiment of the present invention can be evaluated with the use of crystal orientation, for example.

The crystal orientation can be obtained from an FFT pattern obtained by performing FFT processing on a TEM image. Specifically, the directions of the crystal axes can be obtained using an FFT pattern. The FFT pattern obtained by the FFT processing reflects reciprocal lattice space information like an electron diffraction pattern.

When FFT processing is performed on each region in the TEM image of the oxide semiconductor layer, crystal orientation in each region can be obtained. For example, crystal orientation is obtained in each region in a certain area range, so that a map indicating crystal orientation can be formed. Specifically, two spots with high intensity are observed in the FFT pattern of the region including a layered crystal part. The direction of the crystal axis of the region can be obtained from the angle of the line segment connecting the two spots.

In the map showing crystal orientation, the proportion of regions having c-axis alignment is calculated to obtain a c-axis alignment proportion. Here, the region having c-axis alignment represents a region where the orientation is aligned with the c-axis and a region where a difference between the orientation and the c-axis is less than or equal to 20°.

In the oxide semiconductor layer of one embodiment of the present invention, the c-axis orientation rate can be calculated with use of, for example, cross-sectional or plan-view TEM observation of the oxide semiconductor layer. The region where the FFT is performed (also referred to as an FFT window) can be a circle with a diameter of 1.0 nm, for example. Note that the region where the FFT is performed is not limited to a circle.

In the oxide semiconductor layer of one embodiment of the present invention, the c-axis orientation rate is higher than or equal to 60%, preferably higher than or equal to 70%, further preferably higher than or equal to 80%, still further preferably higher than or equal to 90%, yet still further preferably higher than or equal to 95%.

Furthermore, the c-axis orientation rates of a deposition region of the oxide semiconductor 230a, a deposition region of the oxide semiconductor 230b, and a deposition region of the oxide semiconductor 230c are Rc1, Rc2, and Rc3, respectively. Rc2 and Rc3 are each higher than or equal to 60%, preferably higher than or equal to 70%, further preferably higher than or equal to 80%, still further preferably higher than or equal to 90%, yet still further preferably higher than or equal to 95%. Rc3/Rc1 is preferably greater than 1. In addition, Rc2/Rc1 is preferably greater than 1.

Note that after the formation of the oxide semiconductor 230, the boundaries between the oxide semiconductors 230a, 230b, and 230c are not clearly observed in some cases.

The oxide semiconductor 230 of one embodiment of the present invention can be divided into three regions: a first region, a second region, and a third region in this order from the top of the layer 229. Each of the regions is a layered region.

The first region, the second region, and the third region each have a CAAC structure. In addition, the c-axis orientation rate of the third region is preferably higher than that of the first region. The c-axis orientation rate of the second region is preferably higher than that of the first region. In addition, the c-axis orientation rate of each of the second region and the third region is higher than or equal to 80%, preferably higher than or equal to 90%, further preferably higher than or equal to 95%.

The first region is positioned in a range of 0 nm to 3 nm, both inclusive, from the top surface of the layer 229, and the third region is positioned in a range of 0 nm to 3 nm, both inclusive, from the top surface of the oxide semiconductor 230.

Alternatively, the thicknesses of the layers in the regions are substantially equal, for example.

This embodiment can be combined with any of the other embodiments as appropriate. In this specification, in the case where a plurality of structure examples are described in one embodiment, the structure examples can be combined as appropriate.

### Embodiment 3

In this embodiment, a structure example of a semiconductor device 1000 including the memory cell 10 (also referred to as a “memory element”) will be described.

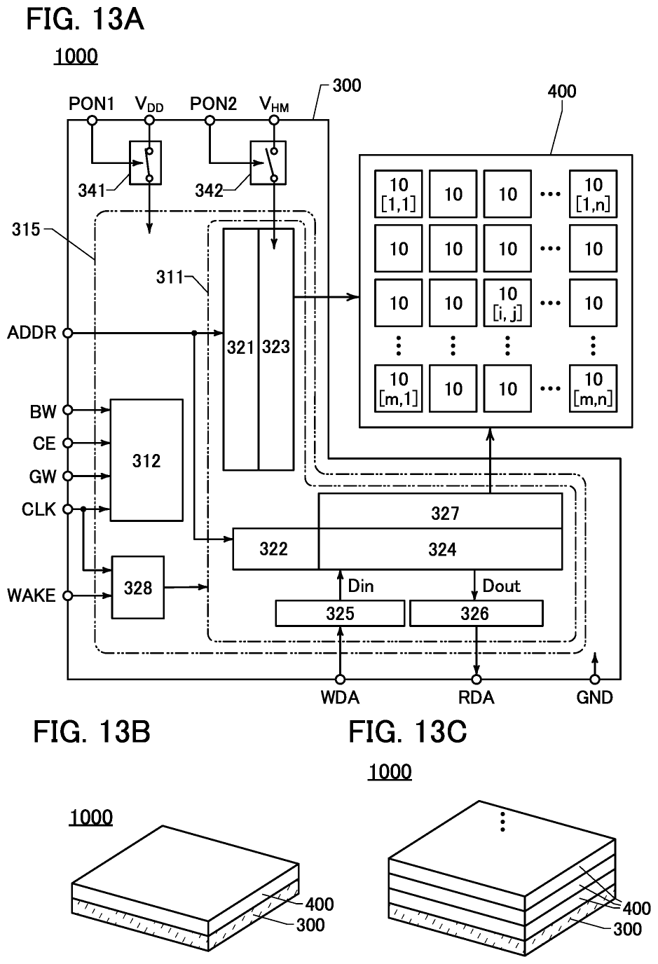

FIG. 13A is a block diagram illustrating a configuration example of the semiconductor device 1000 of one embodiment of the present invention. The semiconductor device 1000 illustrated in FIG. 13A includes a driver circuit 300 and a memory array 400. The memory array 400 includes the plurality of memory cells 10. FIG. 13A illustrates an example in which the memory array 400 includes the plurality of memory cells 10 arranged in a matrix of m rows and n columns (each of m and n is an integer greater than or equal to 2).

Note that the rows and columns extend in the directions orthogonal to each other. In this embodiment, the X direction is referred to as a “row” and the Y direction is referred to as a “column”, but the X direction may be referred to as a “column” and the Y direction may be referred to as a “row”.

In FIG. 13A, the memory cell 10 in the first row and the first column is referred to as a memory cell 10[1, 1], and the memory cell 10 in the m-th row and the n-th column is referred to as a memory cell 10[m, n]. Similarly, the memory cell 10 in the i-th row and j-th column (i is an integer greater than or equal to 1 and less than or equal to m; and j is an integer greater than or equal to 1 and less than or equal to n) is referred to as a memory cell 10 [i,j].

The driver circuit 300 includes a PSW (power switch) 341, a PSW 342, and a peripheral circuit 315. The peripheral circuit 315 includes a peripheral circuit 311, a control circuit 312, and a voltage generation circuit 328.

In the semiconductor device 1000, each circuit, each signal, and each voltage can be appropriately selected as needed. Alternatively, another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal, the signal GW is a global write enable signal, and the signal BW is a byte write enable signal. The signal ADDR is an address signal. The signal WDA is write data, and the signal RDA is read data. The signals PON1 and PON2 are power gating control signals. Note that the signals PON1 and PON2 may be generated in the control circuit 312.

The control circuit 312 is a logic circuit having a function of controlling the overall operation of the semiconductor device 1000. For example, the control circuit 312 performs a logical operation on the signals CE, GW, and BW to determine an operation mode of the semiconductor device 1000 (e.g., a write operation or a read operation). Alternatively, the control circuit 312 generates a control signal for the peripheral circuit 311 so that the operation mode is executed.

The voltage generation circuit 328 has a function of generating a voltage. The signal WAKE has a function of controlling the input of the signal CLK to the voltage generation circuit 328. For example, when an H-level signal is applied as the signal WAKE, the signal CLK is input to the voltage generation circuit 328, and the voltage generation circuit 328 generates a voltage.

The peripheral circuit 311 is a circuit for writing and reading data to/from the memory cell 10. The peripheral circuit 311 includes a row decoder 321, a column decoder 322, a row driver 323, a column driver 324, an input circuit 325, an output circuit 326, and a sense amplifier 327.

The row decoder 321 and the column decoder 322 have a function of decoding the signal ADDR. The row decoder 321 is a circuit for specifying a row to be accessed, and the column decoder 322 is a circuit for specifying a column to be accessed. The row driver 323 has a function of selecting a wiring specified by the row decoder 321. The column driver 324 has a function of writing data to the memory cell 10, a function of reading data from the memory cell 10, a function of retaining the read data, and the like.

The input circuit 325 has a function of retaining the signal WDA. Data retained by the input circuit 325 is output to the column driver 324. Data output from the input circuit 325 is data (Din) to be written to the memory cell 10. Data (Dout) read from the memory cell 10 by the column driver 324 is output to the output circuit 326. The output circuit 326 has a function of retaining Dout. In addition, the output circuit 326 has a function of outputting Dout to the outside of the semiconductor device 1000. Data output from the output circuit 326 is the signal RDA.

The PSW 341 has a function of controlling the supply of V_{DD} to the peripheral circuit 315. The PSW 342 has a function of controlling the supply of V_{HM} to the row driver 323. Here, in the semiconductor device 1000, a high power supply voltage is V_{DD} and a low power supply voltage is GND (a ground potential). In addition, V_{HM} is a high power supply voltage used to set the word line to the H level and is higher than V_{DD}. The on/off of the PSW 341 is controlled by the signal PON1, and the on/off of the PSW 342 is controlled by the signal PON2. The number of power domains to which V_{DD} is supplied is one in the peripheral circuit 315 in FIG. 13A but can be more than one. In this case, a power switch is provided for each power domain.

The driver circuit 300 and the memory array 400 may be provided on the same plane. As illustrated in FIG. 13B, the driver circuit 300 and the memory array 400 may be provided to overlap with each other. When the driver circuit 300 and the memory array 400 overlap with each other, the signal transmission distance can be shortened. In addition, the semiconductor device 1000 can be reduced in size.

As illustrated in FIG. 13C, a plurality of memory arrays 400 may be stacked over the driver circuit 300. When the plurality of memory arrays 400 are provided over the driver circuit 300 to overlap with each other, the memory capacity per unit area can be increased.

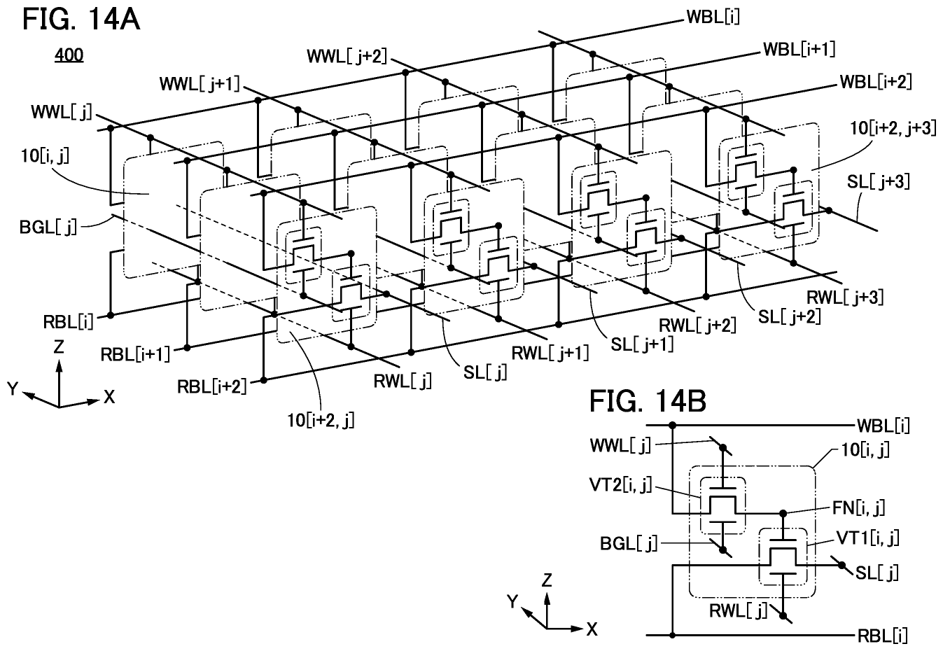

FIG. 14A is a block diagram illustrating an arrangement example of the memory cells 10 in the memory array 400. The memory array 400 includes m wirings WBL and m wirings RBL which extend in the row direction, and n wirings WWL, n wirings SL, n wirings BGL, and n wirings RWL which extend in the column direction (not illustrated).

FIG. 14B is a circuit diagram of the memory cell 10[i,j]. The memory cell 10[i,j] includes a transistor VT2[i,j] and a transistor VT1[i,j]. A gate of the transistor VT2[i,j] is connected to a wiring WWL[j], which is the wiring WWL in the j-th column, and a back gate thereof is connected to a wiring BGL[j], which is the wiring BGL in the j-th column. One of a source and a drain of the transistor VT2[i,j] is connected to a wiring WBL[i], which is the wiring WBL in the i-th row, and the other thereof is connected to a gate of the transistor VT1[i,j].

A back gate of the transistor VT1[i,j] is connected to a wiring RWL[j], which is the wiring RWL in the j-th column. One of a source and a drain of the transistor VT1[i,j] is connected to a wiring RBL[i], which is the wiring RBL in the i-th row, and the other thereof is connected to a wiring SL[j], which is the wiring SL in the j-th column.

The memory cell 10[i,j] includes a node FN[i,j]. The node FN[i,j] is a node in which the other of the source and the drain of the transistor VT2[i,j] is connected to the gate of the transistor VT1[i,j].

When a signal is supplied to the wiring WBL[i] and the wiring WWL[j], data can be written to the memory cell 10[i,j]. When a signal is supplied to the wiring RBL[i] and the wiring RWL[j], data retained in the memory cell 10[i,j] can be read. By controlling signals supplied to the wirings, data reading and data writing can be performed on a desired memory cell 10. Thus, the semiconductor device 1000 can function as a NOR memory device.

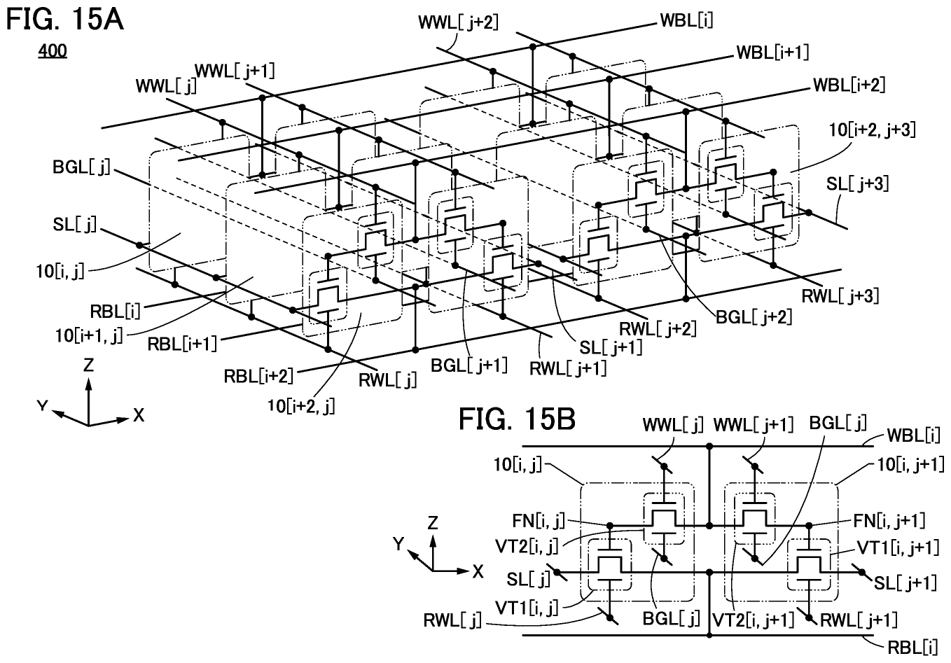

FIG. 15A is a block diagram illustrating an arrangement example of the memory cells 10 in the memory array 400, which is different from that in FIG. 14A.

In the memory array 400 illustrated in FIG. 15A, the memory cells 10 in the odd-number columns and the memory cells 10 in the even-number columns are bilaterally symmetrically placed. FIG. 15B is a circuit diagram illustrating the memory cell 10[i,j] and a memory cell 10[i,j+1] in the case where j is an odd number. One of the source and the drain of the transistor VT2[i,j] and one of a source and a drain of the transistor VT2[i,j+1] are each connected to the wiring WBL[i]. By bilaterally symmetrical arrangement of the memory cells 10 in the odd-number column and the memory cells 10 in the even-number column, both the transistor VT2[i,j] and the transistor VT2[i,j+1] can be connected to the wiring WBL[i] through a common connection path.

Similarly, each of the transistor VT1[i,j] and a transistor VT1[i,j+1] can be connected to the wiring RBL[i] through a common connection path. Accordingly, the occupied area of the memory array 400 can be further reduced. Furthermore, the record density per unit area can be further increased.

This embodiment can be implemented in appropriate combination with any of the structures described in the other embodiments and the like.

### Embodiment 4

In this embodiment, application examples of the memory device of one embodiment of the present invention will be described.

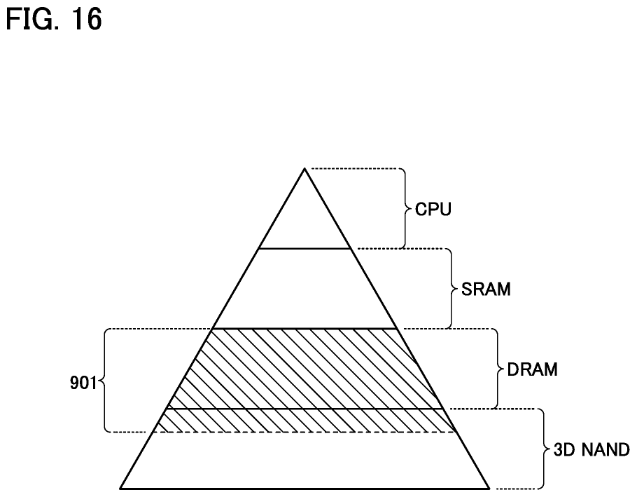

In general, a variety of memory devices are used in semiconductor devices such as computers in accordance with the intended use. FIG. 16 shows a hierarchy diagram showing various memory devices with different levels. The memory devices at the upper levels require high access speeds, and the memory devices at the lower levels require large memory capacity and high record density. In FIG. 16, sequentially from the top level, a memory included as a register in an arithmetic processing device such as a CPU, a SRAM (Static Random Access Memory), a DRAM (Dynamic Random Access Memory), and a 3D NAND memory are shown.

A memory included as a register in an arithmetic processing device such as a CPU is used for temporary storage of arithmetic operation results, for example, and thus is frequently accessed by the arithmetic processing device. Accordingly, high operation speed is required rather than memory capacity. The register also has a function of retaining settings of the arithmetic processing device, for example.

An SRAM is used for a cache, for example. The cache has a function of retaining a copy of part of data retained in a main memory. Copying data which is frequently used and retaining the copy of the data in the cache facilitates rapid data access.

A DRAM is used for the main memory, for example. The main memory has a function of retaining a program or data which are read from the storage. The record density of a DRAM is approximately 0.1 to 0.3 Gbit/mm².

A 3D NAND memory is used for the storage, for example. The storage has a function of retaining data that needs to be stored for a long time and programs used in the arithmetic processing device, for example. Therefore, the storage needs to have a large memory capacity and a high record density rather than operating speed. The record density of a memory device used for the storage is approximately 0.6 to 6.0 Gbit/mm².

Not only can the memory device of one embodiment of the present invention operate at a high speed and retain data for a long time, but also high rewrite endurance and low-voltage driving can be achieved. The memory device of one embodiment of the present invention can be favorably used as a memory device in a boundary region 901 that includes both the level including the main memory and the level including the storage.

The memory device of one embodiment of the present invention can be applied to, for example, memory devices of a variety of electronic devices (e.g., information terminals, computers, smartphones, e-book readers, digital still cameras, video cameras, video recording/reproducing devices, navigation systems, and game machines). The memory device can also be used for image sensors, IoT (Internet of Things), healthcare devices, and the like. Here, the computers refer not only to tablet computers, notebook computers, and desktop computers, but also to large computers such as server systems.

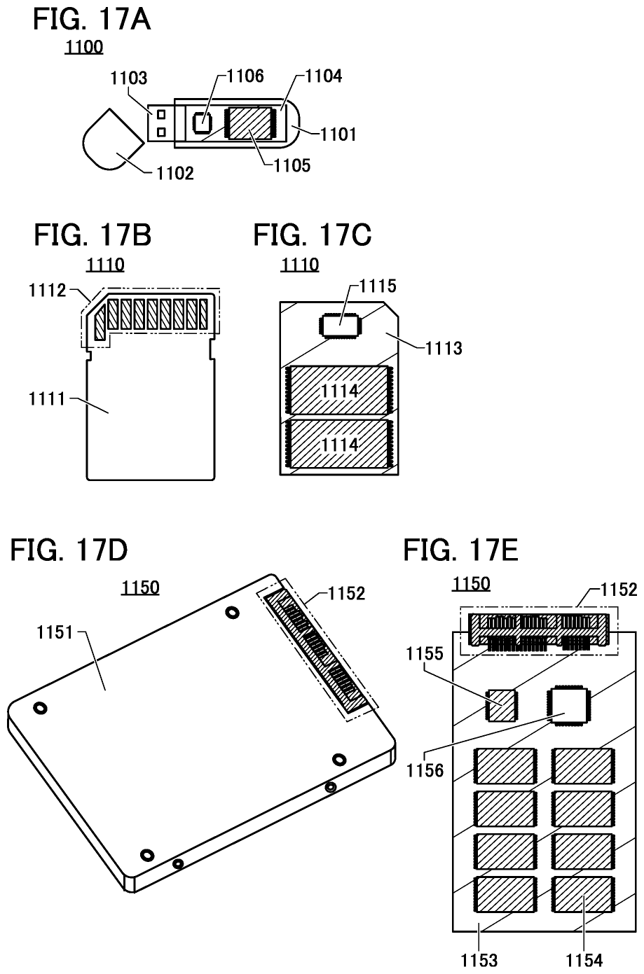

Alternatively, the memory device of one embodiment off the present invention is applied to a variety of removable memory devices such as memory cards (e.g., SD cards), USB memories, and SSDs (solid state drives). FIGS. 17A to 17E schematically show some structure examples of removable memory devices. The memory device of one embodiment of the present invention is processed into a packaged memory chip and used in a variety of storage devices and removable memories, for example.

FIG. 17A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The semiconductor device described in the above embodiment can be incorporated in the memory chip 1105 or the like on the substrate 1104.

FIG. 17B is a schematic external view of an SD card, and FIG. 17C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. In this case, data can be read from and written in the memory chip 1114 by radio communication between a host device and the SD card 1110. The semiconductor device described in the above embodiment can be incorporated in the memory chip 1114 or the like on the substrate 1113.

FIG. 17D is a schematic external view of an SSD, and FIG. 17E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The semiconductor device described in the above embodiment can be incorporated in the memory chip 1154 or the like on the substrate 1153.

This embodiment can be implemented in appropriate combination with any of the structures described in the other embodiments and the like.

### Embodiment 5

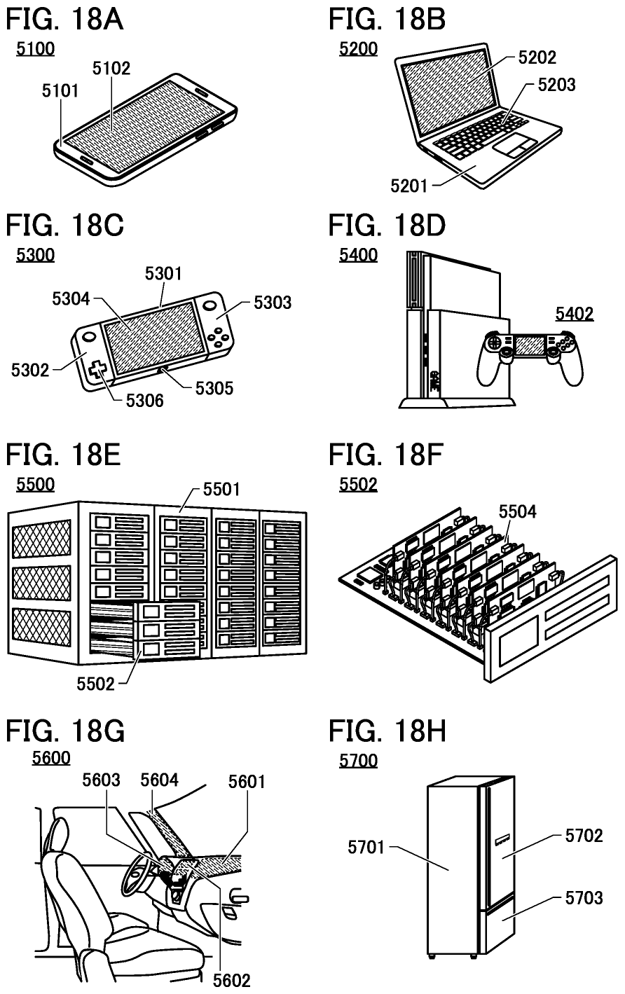

FIGS. 18A to 18H illustrate specific examples of electronic devices each including the semiconductor device of one embodiment of the present invention.

### <Electronic Device and System>

The semiconductor device of one embodiment of the present invention can be mounted on a variety of electronic devices. Examples of electronic devices include a digital camera, a digital video camera, a digital photo frame, an e-book reader, a mobile phone, a portable game machine, a portable information terminal, and an audio reproducing device in addition to electronic devices provided with a relatively large screen, such as a television device, a monitor for a desktop or notebook information terminal or the like, digital signage, and a large game machine like a pachinko machine. In addition, the semiconductor device of one embodiment of the present invention can be used as a component of artificial intelligence. With use of the semiconductor device of one embodiment of the present invention, artificial intelligence can be included in the electronic device.

The electronic device of one embodiment of the present invention may include an antenna. When a signal is received by the antenna, a video, information, or the like can be displayed on a display portion. When the electronic device includes an antenna and a secondary battery, the antenna may be used for contactless power transmission.

The electronic device of one embodiment of the present invention may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of one embodiment of the present invention can have a variety of functions. For example, the electronic device can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading a program or data stored in a recording medium.

### [Information Terminal]

FIG. 18A illustrates a mobile phone (a smartphone), which is a type of information terminal. An information terminal 5100 includes a housing 5101 and a display portion 5102. As input interfaces, a touch panel is provided in the display portion 5102, and a button is provided in the housing 5101.

The information terminal 5100 can execute an application utilizing artificial intelligence by using the semiconductor device of one embodiment of the present invention. Examples of the application utilizing artificial intelligence include an application for recognizing a conversation and displaying the content of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 18B illustrates a notebook information terminal 5200. The notebook information terminal 5200 includes a main body 5201 of the information terminal, a display portion 5202, and a keyboard 5203.

Like the information terminal 5100 described above, the notebook information terminal 5200 can execute an application utilizing artificial intelligence by using the semiconductor device of one embodiment of the present invention. Examples of the application utilizing artificial intelligence include design-support software, text correction software, and software for automatic menu generation. Furthermore, with the use of the notebook information terminal 5200, novel artificial intelligence can be developed.

Note that although FIGS. 18A and 18B show a smartphone and a notebook information terminal, respectively, as examples of the electronic device in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machines]

FIG. 18C shows a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In that case, the housing 5302 and the housing 5303 can each function as an operating unit. Thus, a plurality of players can play a game at the same time. The semiconductor device of one embodiment of the present invention can be incorporated into a chip provided on a substrate in the housing 5301, the housing 5302, and the housing 5303, for example.

FIG. 18D shows a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, the peripheral circuit, and the module can be reduced.

Furthermore, when the semiconductor device of one embodiment of the present invention is used in the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, variations in questions posed by the player, the progress of the game, time, and the actions and words of the game characters can be expressed.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are shown as examples of game machines in FIGS. 18C and 18D, the game machine capable of using the semiconductor device of one embodiment of the present invention is not limited thereto. Examples of the game machine using the semiconductor device of one embodiment of the present invention include an arcade game machine installed in entertainment facilities (a game center, an amusement park, and the like), and a throwing machine for batting practice installed in sports facilities.

### [Large Computer]

The semiconductor device of one embodiment of the present invention can be used in a large computer.

FIG. 18E shows a supercomputer 5500 as an example of a large computer. FIG. 18F shows a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the semiconductor device of one embodiment of the present invention can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the semiconductor device of one embodiment of the present invention in the supercomputer 5500 achieves a low-power-consumption supercomputer. Moreover, heat generation from a circuit can be reduced owing to low power consumption; thus, the influence of heat generation on the circuit, the peripheral circuit, and the module can be reduced.

Although a supercomputer is shown as an example of a large computer in FIGS. 18E and 18F, a large computer using the semiconductor device of one embodiment of the present invention is not limited thereto. Examples of a large computer using the semiconductor device of one embodiment of the present invention include a computer that provides service (a server) and a large general-purpose computer (a mainframe).

### [Moving Vehicle]

The semiconductor device of one embodiment of the present invention can be used in an automobile, which is a moving vehicle, and around a driver's seat in the automobile.

FIG. 18G shows an area around a windshield inside an automobile 5600, which is an example of a moving vehicle. FIG. 18G illustrates a display panel 5601, a display panel 5602, and a display panel 5603 that are attached to a dashboard and a display panel 5604 that is attached to a pillar.

The display panel 5601 to the display panel 5603 can provide a variety of information by displaying a speedometer, a tachometer, mileage, a fuel gauge, a gear state, air-condition setting, and the like. In addition, the content, layout, or the like of the display on the display panels can be changed as appropriate to suit the user's preference, so that the design quality can be increased. The display panel 5601 to the display panel 5603 can also be used as lighting devices.

The display panel 5604 can compensate for the view obstructed by the pillar (a blind spot) by showing a video taken by an imaging device (not illustrated) provided on the automobile. That is, displaying an image taken by the imaging device provided outside the automobile leads to compensation for the blind spot and an increase in safety. In addition, displaying an image to compensate for a portion that cannot be seen makes it possible for the driver to confirm the safety more naturally and comfortably. The display panel 5604 can also be used as a lighting device.

Since the semiconductor device of one embodiment of the present invention can be used as a component of artificial intelligence, the chip can be used for an automatic driving system of the automobile, for example. The chip can also be used for a system for navigation, risk prediction, or the like. A structure may be employed in which the display panel 5601 to the display panel 5604 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the semiconductor device of one embodiment of the present invention is used in these moving vehicles.

### [Household Appliance]

FIG. 18H shows an electric refrigerator-freezer 5700 as an example of a household appliance. The electric refrigerator-freezer 5700 includes a housing 5701, a refrigerator door 5702, a freezer door 5703, and the like.

When the semiconductor device of one embodiment of the present invention is used in the electric refrigerator-freezer 5700, the electric refrigerator-freezer 5700 including artificial intelligence can be achieved. Utilizing the artificial intelligence enables the electric refrigerator-freezer 5700 to have a function of automatically making a menu based on foods stored in the electric refrigerator-freezer 5700, expiration dates of the foods, or the like, a function of automatically adjusting temperature to be appropriate for the foods stored in the electric refrigerator-freezer 5700, and the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic devices, the functions of the electronic devices, the application examples of artificial intelligence, their effects, and the like described in this embodiment can be combined as appropriate with the description of another electronic device.

This embodiment can be implemented in appropriate combination with any of the structures described in the other embodiments and the like.

<Notes on Description of this Specification and the Like>

The following are notes on the description of the foregoing embodiments and the structures in the embodiments.

One embodiment of the present invention can be constituted by appropriately combining the structure described in an embodiment with any of the structures described in the other embodiments. In addition, in the case where a plurality of structure examples are described in one embodiment, the structure examples can be combined as appropriate.

Note that a content (or part thereof) in an embodiment can be applied to, combined with, or replaced with another content (or part thereof) in the same embodiment and/or a content (or part thereof) in another embodiment or other embodiments.

Note that in each embodiment, a content described in the embodiment is a content described with reference to a variety of diagrams or a content described with text in the specification.

Note that by combining a diagram (or part thereof) described in one embodiment with another part of the diagram, a different diagram (or part thereof) described in the embodiment, and/or a diagram (or part thereof) described in another embodiment or other embodiments, much more diagrams can be created.

In this specification and the like, components are classified on the basis of the functions and shown as blocks independent of each other in block diagrams. However, in an actual circuit and the like, such components are sometimes hard to classify functionally, and there is a case where one circuit is associated with a plurality of functions or a case where a plurality of circuits are associated with one function. Therefore, the segmentation of a block in the block diagrams is not limited by any of the components described in the specification, and can be differently determined as appropriate depending on situations.

In drawings, the size, the layer thickness, or the region is determined arbitrarily for description convenience. Therefore, the size, the layer thickness, or the region is not limited to the illustrated scale. Note that the drawings are schematically shown for clarity, and an embodiment of the present invention is not limited to shapes or values shown in the drawings. For example, the following can be included: a variation in a signal, a voltage, or a current due to noise or difference in timing.

Note that the term “over” or “under” in this specification and the like does not necessarily mean that a component is placed directly over and in contact with or directly under and in contact with another component. For example, the expression “an electrode B over an insulating layer A” does not necessarily mean that the electrode B is on and in direct contact with the insulating layer A, and can mean the case where another component is provided between the insulating layer A and the electrode B.

In this specification and the like, “parallel” indicates a state where two straight lines are placed at an angle of greater than or equal to −10° and less than or equal to 10°, for example.

Accordingly, the case where the angle is greater than or equal to −5° and less than or equal to 5° is also included. The terms “perpendicular” and “orthogonal” indicates that the angle formed between two straight lines is greater than or equal to 80° and less than or equal to 100°, for example. Accordingly, the case where the angle is greater than or equal to 85° and less than or equal to 95° is also included.

Note that the ordinal numbers such as “first” and “second” in this specification and the like are used in order to avoid confusion among components and do not denote the priority or the order such as the order of steps or the stacking order. A term without an ordinal number in this specification and the like might be provided with an ordinal number in a claim in order to avoid confusion among components. A term with an ordinal number in this specification and the like might be provided with a different ordinal number in a claim. Moreover, a term with an ordinal number in this specification and the like might not be provided with any ordinal number in a claim and the like.

In this specification and the like, the expressions “one of a source and a drain” (or a first electrode or a first terminal) and “the other of the source and the drain” (or a second electrode or a second terminal) are used to describe the connection relation of a transistor. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation.

In addition, in this specification and the like, the term such as an “electrode” or a “wiring” does not limit a function of the component. For example, an “electrode” is used as part of a wiring in some cases, and vice versa. Moreover, the term “electrode” or “wiring” also includes the case where a plurality of “electrodes” or “wirings” are formed in an integrated manner, for example.

In this specification and the like, voltage and potential can be interchanged with each other as appropriate. The term “voltage” refers to a potential difference from a reference potential. When the reference potential is a ground voltage, for example, “voltage” can be replaced with “potential”. The ground potential does not necessarily mean 0 V. Potentials are relative values, and the potential applied to a wiring or the like is changed depending on the reference potential, in some cases.

Note that in this specification and the like, the terms such as “film” and “layer” can be interchanged with each other depending on the case or circumstances. For example, the term “conductive layer” can be changed into the term “conductive film” in some cases. For another example, the term “insulating film” can be changed into the term “insulating layer” in some cases.

In this specification and the like, a switch is in a conduction state (on state) or in a non-conduction state (off state) to determine whether a current flows therethrough or not. Alternatively, a switch has a function of selecting and changing a current path.

Note that in this specification and the like, an “on state” of a transistor refers to a state in which a source and a drain of the transistor are electrically short-circuited (also referred to as a “conduction state”). Furthermore, an “off state” of the transistor refers to a state in which the source and the drain of the transistor are electrically disconnected (also referred to as a “non-conduction state”).

In this specification and the like, “on-state current” sometimes means a current that flows between a source and a drain when a transistor is on. In addition, “off-state current” sometimes means a current that flows between a source and a drain when a transistor is off.

In this specification and the like, the channel length of a planar transistor refers to, for example, the distance between a source and a drain in a region where a semiconductor (or a portion where a current flows in a semiconductor when a transistor is on) and a gate overlap each other, or a region where a channel is formed in a top view of the transistor.

In this specification and the like, the channel width refers to, for example, the length of a portion where a source and a drain face each other in a region where a semiconductor (or a portion where current flows in a semiconductor when a transistor is on) and a gate electrode overlap each other, or a region where a channel is formed.

In this specification and the like, a node can be referred to as a terminal, a wiring, an electrode, a conductive layer, a conductor, an impurity region, and the like depending on the circuit structure, the device structure, and the like. Furthermore, a terminal, a wiring, and the like can be referred to as a node.

Note that the expression “A and B are connected” in this specification and the like also means electrical connection between A and B. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when represented by an equivalent circuit.

This application is based on Japanese Patent Application Serial No. 2023-123020 filed with Japan Patent Office on Jul. 28, 2023, the entire contents of which are hereby incorporated by reference.

What is claimed is:

1. A memory device comprising:
a memory cell comprising a first transistor and a second transistor over the first transistor,
wherein the first transistor comprises a first oxide semiconductor layer, a first conductive layer, a second conductive layer, a third conductive layer, a fourth conductive layer, a first insulating layer, and a second insulating layer,
wherein the second transistor comprises a second oxide semiconductor layer, the first conductive layer, a fifth conductive layer, a sixth conductive layer, a seventh conductive layer, a third insulating layer, and a fourth insulating layer,
wherein in a cross-sectional view of the first transistor, the first oxide semiconductor layer faces the first conductive layer with the first insulating layer therebetween and faces the second conductive layer with the second insulating layer therebetween,
wherein in a cross-sectional view of the second transistor, the second oxide semiconductor layer faces the fifth conductive layer with the third insulating layer therebetween and faces the sixth conductive layer with the fourth insulating layer therebetween,
wherein the first oxide semiconductor layer is over and in contact with the third conductive layer and the fourth conductive layer,
wherein the second oxide semiconductor layer is over and in contact with the first conductive layer and the seventh conductive layer,
wherein in a cross-sectional view of the memory cell, the third conductive layer is overlapped with the first conductive layer, the second conductive layer, the fourth conductive layer, the fifth conductive layer, the sixth conductive layer, and the seventh conductive layer,
wherein a first potential supplied to the second conductive layer in a period in which data is written to the memory cell is higher than a second potential supplied to the second conductive layer in a period in which the data is retained in the memory cell,
wherein a third potential supplied to the sixth conductive layer in a period in which the data is read from the memory cell is higher than a fourth potential supplied to the sixth conductive layer in a period in which the data is retained in the memory cell,
wherein the third potential is lower than the first potential, and
wherein the fourth potential is lower than the second potential.

2. The memory device according to claim 1,
wherein the memory cell comprises a capacitor, and
wherein one electrode of the capacitor is electrically connected to the first conductive layer.

3. The memory device according to claim 2, wherein the other electrode of the capacitor is electrically connected to the sixth conductive layer.

4. The memory device according to claim 1, wherein the first insulating layer or the second insulating layer comprises hafnium, zirconium, and oxygen.

5. The memory device according to claim 1, wherein each of the first oxide semiconductor layer and the second oxide semiconductor layer comprises at least indium.

6. The memory device according to claim 1, wherein in a plan view of the first transistor, the first conductive layer is surrounded by the first oxide semiconductor layer and the first oxide semiconductor layer is surrounded by the second conductive layer.

7. A memory device comprising:
a memory cell comprising a first transistor and a second transistor over the first transistor,
wherein the first transistor comprises a first oxide semiconductor layer, a first conductive layer, a second conductive layer, a third conductive layer, a fourth conductive layer, a first insulating layer, and a second insulating layer,
wherein the second transistor comprises a second oxide semiconductor layer, the first conductive layer, a fifth conductive layer, a sixth conductive layer, a seventh conductive layer, a third insulating layer, and a fourth insulating layer,
wherein the third conductive layer, the second conductive layer, the fourth conductive layer, the first conductive layer, the sixth conductive layer, the seventh conductive layer, and the fifth conductive layer are stacked in this order and overlap with one another,
wherein in a cross-sectional view of the first transistor, the first oxide semiconductor layer is over and in contact with the fourth conductive layer and the third conductive layer through an opening in the second conductive layer and an opening in the fourth conductive layer,
wherein in the cross-sectional view of the first transistor, the first oxide semiconductor layer faces the first conductive layer with the first insulating layer therebetween and faces the second conductive layer with the second insulating layer therebetween,
wherein in a cross-sectional view of the second transistor, the second oxide semiconductor layer is over and in contact with the seventh conductive layer and the first conductive layer through an opening in the sixth conductive layer and an opening in the seventh conductive layer,
wherein in a cross-sectional view of the second transistor, the second oxide semiconductor layer faces the fifth conductive layer with the third insulating layer therebetween and faces the sixth conductive layer with the fourth insulating layer therebetween,
wherein a first potential supplied to the second conductive layer in a period in which data is written to the memory cell is higher than a second potential supplied to the second conductive layer in a period in which the data is retained in the memory cell,
wherein a third potential supplied to the sixth conductive layer in a period in which the data is read from the memory cell is higher than a fourth potential supplied to the sixth conductive layer in a period in which the data is retained in the memory cell,
wherein the third potential is lower than the first potential, and
wherein the fourth potential is lower than the second potential.

8. The memory device according to claim 7,
wherein the memory cell comprises a capacitor, and
wherein one electrode of the capacitor is electrically connected to the first conductive layer.

9. The memory device according to claim 8, wherein the other electrode of the capacitor is electrically connected to the sixth conductive layer.

10. The memory device according to claim 7, wherein the first insulating layer or the second insulating layer comprises hafnium, zirconium, and oxygen.

11. The memory device according to claim 7, wherein each of the first oxide semiconductor layer and the second oxide semiconductor layer comprises at least indium.

12. The memory device according to claim 7, wherein in a plan view of the first transistor, the first conductive layer is surrounded by the first oxide semiconductor layer and the first oxide semiconductor layer is surrounded by the second conductive layer.
